(19) United States
(12) Patent Application Publication
(10) Pub. No.: US 2017/0207421 A1
(43) Pub. Date: Jul. 20, 2017

(54) ORGANIC ELECTROLUMINESCENT ELEMENT, BASE MATERIAL, AND LIGHT EMITTING DEVICE

(71) Applicant: PANASONIC INTELLECTUAL PROPERTY MANAGEMENT CO., LTD., Osaka (JP)

(72) Inventors: Jumpei MATSUZAKI, Hyogo (JP); Kazuyuki YAMAE, Nara (JP)

(73) Assignee: PANASONIC INTELLECTUAL PROPERTY MANAGEMENT CO., LTD., Osaka (JP)

(21) Appl. No.: 15/326,250

(22) PCT Filed: Aug. 28, 2015
(86) PCT No.: PCT/JP2015/004348

§ 371 Date: Jan. 13, 2017

(30) Foreign Application Priority Data
Sep. 25, 2014 (JP) 2014-195729

(51) Int. Cl. H01L 51/52; H01L 51/00

(52) U.S. Cl. CPC H01L 51/5275; H01L 51/0096; H01L 51/5253

(57) ABSTRACT

An organic electroluminescent element includes at least one light emitting layer, a high refractive index layer (first layer), and a low refractive index layer (second layer). An uneven structure including a plurality of protrusions each having two or more steps is provided at an interface between the high refractive index layer and the low refractive index layer. The organic electroluminescent element includes a protective layer. The protective layer is a layer disposed between the second layer (low refractive index layer) and a light-exiting surface of the organic electroluminescent element or is the second layer (low refractive index layer). Relationships expressed as n₀<n₁ and n₂≦n₁ are satisfied, where n₀ is a refractive index of an atmosphere, n₁ is a refractive index of the protective layer, and n₂ is a refractive index of the low refractive index layer.

### TECHNICAL FIELD

The present disclosure relates to organic electroluminescent elements.

### BACKGROUND ART

A generally known organic electroluminescent element (hereinafter referred to as “organic EL element”) includes a substrate and a light emitting body, and the light emitting body includes an anode, a hole transport layer, a light emitting layer, an electron transport layer, and a cathode which are stacked on a surface of the substrate. In this organic EL element, light is produced in the light emitting layer when a voltage is applied between the anode and the cathode, and the produced light is extracted outside through the electrode which is light transmissive.

Many attempts have been made to increase the light-outcoupling efficiency of the organic EL element. In the organic EL element, total reflection due to a difference between refractive indices, absorption of light by materials, and other causes may hinder light produced in the light emitting layer from going outside. Therefore, increasing the light-outcoupling efficiency can increase the efficiency of the organic EL element. For example, when a light reflective electrode is provided, the light reflective electrode reflects light emitted from the light emitting layer to allow the light to travel toward an opposite side (toward the light transmissive electrode), thereby collecting light in one direction to readily output the light. In this way, the light-outcoupling efficiency can be increased.

In a case of a structure in which light is emitted through a substrate, reducing the total reflection of light at the substrate is effective to increase the light-outcoupling efficiency. WO 2014/057647 A1 proposes that an uneven structure is provided to increase light incident on a substrate, thereby extracting more light. It is important to further improve light-outcoupling efficiencies in organic EL elements.

### SUMMARY OF INVENTION

The present disclosure would aim to provide an organic electroluminescent element having high light-outcoupling efficiency.

An organic electroluminescent element is disclosed. The organic electroluminescent element includes at least one light emitting layer, a first layer disposed between the at least one light emitting layer and a light-exiting surface of the organic electroluminescent element, and a second layer disposed between the first layer and the light-exiting surface and adjoining the first layer. An uneven structure including a plurality of protrusions each having two or more steps is provided at an interface between the first layer and the second layer. The organic electroluminescent element includes a protective layer which is a layer disposed between the second layer and the light-exiting surface or is the second layer. Relationships expressed as n₀<n₁ and n₂≦n₁ are satisfied, where n₀ is a refractive index of an atmosphere, n₁ is a refractive index of the protective layer, and n₂ is a refractive index of the second layer.

A base material is disclosed. The base material includes a first layer and a second layer adjoining the first layer. An uneven structure including a plurality of protrusions each having two or more steps is provided at an interface between the first layer and the second layer. The base material includes a protective layer which is a layer adjoining the second layer or is the second layer. Relationships expressed as n₀<n₁ and n₂≦n₁ are satisfied, where n₀ is a refractive index of an atmosphere, n₁ is a refractive index of the protective layer, and n₂ is a refractive index of the second layer.

A light emitting device is disclosed. The light emitting device includes the organic electroluminescent element and a cable.

The organic electroluminescent element of the present disclosure is excellent in light-outcoupling efficiency.

The base material of the present disclosure can provide an organic electroluminescent element excellent in light-outcoupling efficiency.

The light emitting device of the present disclosure is excellent in light-outcoupling efficiency.

### BRIEF DESCRIPTION OF DRAWINGS

FIG. 1 is a schematic sectional view illustrating an example of an organic electroluminescent element;

FIGS. 2A to 2E are schematic sectional views for illustrating uneven structures. FIG. 2A is a view illustrating an interface without the uneven structure, FIG. 2B is a view illustrating an uneven structure having one-stepped protrusions, FIG. 2C is a view illustrating an uneven structure having two-stepped protrusion, FIG. 2D is a view illustrating an uneven structure having three-stepped protrusions, and FIG. 2E is a view illustrating an uneven structure having four-stepped protrusions;

FIG. 3 is a schematic diagram illustrating traveling of emitted light;

FIG. 4 is a graph illustrating the relationship between the number of levels of the uneven structure and the efficiency of −1-order transmission diffraction light;

FIG. 5A is a graph illustrating the relationship between the distance between a light emitting layer and a reflective layer and the distribution of modes of light, and FIG. 5B is a graph illustrating the relationship between the incident angle of light to be extracted and the distance between the light emitting layer and the reflective layer;

FIGS. 6A to 6C are views illustrating the light-outcoupling effect of the uneven structure. FIG. 6A is a schematic diagram illustrating the parameters of the uneven structure, FIG. 6B is the light transmittance in the case of the uneven structure having one-stepped protrusions, and FIG. 6C is the light transmittance in the case of the uneven structure having two-stepped protrusions;

FIG. 7 is a schematic sectional view illustrating an example of the organic electroluminescent element;

FIG. 8 is a schematic sectional view illustrating an example of the organic electroluminescent element;

FIG. 9 is a schematic sectional view illustrating an example of the organic electroluminescent element;

FIG. 10 is a schematic sectional view illustrating an example of the organic electroluminescent element;

FIG. 11 is a schematic sectional view illustrating an example of the organic electroluminescent element;

FIG. 12 is a schematic sectional view illustrating an example of the organic electroluminescent element;

FIG. 13 is a schematic plan view illustrating an example of a regular uneven structure;

FIG. 14 is a schematic plan view illustrating an example of the regular uneven structure;

FIG. 15 is a schematic plan view illustrating an example of a random uneven structure;

FIG. 16 is a schematic plan view illustrating an example of the random uneven structure;

FIG. 17 is a sectional view illustrating an example of a base material;

FIGS. 18A to 18C are sectional views illustrating an example of a method for fabricating the base material, wherein FIG. 18A, FIG. 18B and FIG. 18C each illustrate the base material in a step in the method;

FIG. 19 is a sectional view illustrating an example of the base material;

FIGS. 20A to 20D are sectional views illustrating an example of a method for fabricating the base material. FIG. 20A, FIG. 20B, FIG. 20C, and FIG. 20D illustrate partially-fabricated base materials; and

FIG. 21 is a perspective view illustrating an example of the light emitting device.

### DESCRIPTION OF EMBODIMENTS

An organic electroluminescent element (organic EL element) will be disclosed below. Specifically, an organic electroluminescent element with improved light-outcoupling efficiency is disclosed. The organic EL element will be described below with reference to the drawings. In the drawings, layers and structures are schematically illustrated. The drawings may be not to scale.

An organic EL element 1 disclosed below includes at least one light emitting layer 41, a first layer disposed between the light emitting layer 41 and a light-exiting surface defined as a surface of the organic EL element through which light exits outside, and a second layer disposed between the first layer and the light-exiting surface and adjoining the first layer. An uneven structure 20 including a plurality of protrusions 23 each having two or more steps is provided at an interface between the first layer and the second layer. The organic EL element 1 includes a protective layer 10. The protective layer 10 is a layer disposed between the second layer and the light-exiting surface or is the second layer. Relationships expressed as n₀<n₁ and n₂≦n₁ are satisfied, where n₀ is the refractive index of the atmosphere, n₁ is the refractive index of the protective layer, and n₂ is the refractive index of the second layer.

First, description is made to an aspect in which the protective layer 10 is a layer disposed between the second layer and the light-exiting surface, that is, an aspect in which the protective layer 10 is a layer different from the second layer.

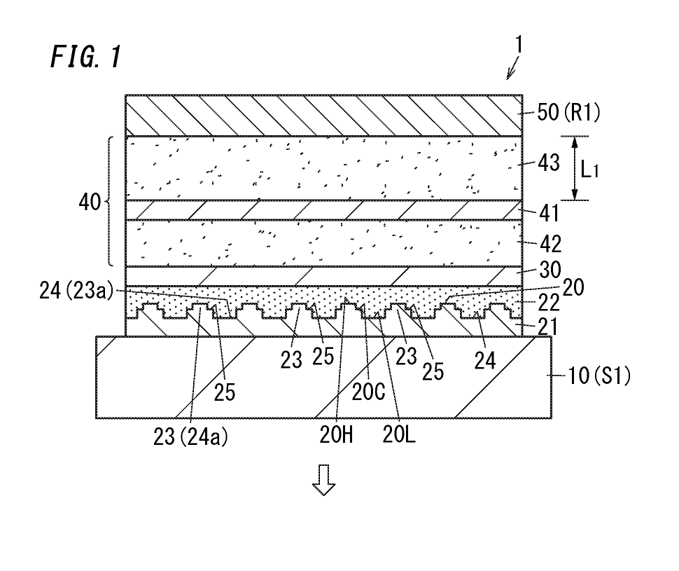

FIG. 1 is a schematic sectional view illustrating an organic EL element 1. The organic EL element 1 includes at least one light emitting layer 41, a first layer, a second layer, and a protective layer 10. The first layer is defined as a high refractive index layer 22. The high refractive index layer 22 is disposed between the light emitting layer 41 and the light-exiting surface. The second layer is defined as a low refractive index layer 21. The low refractive index layer 21 is disposed between the high refractive index layer 22 and the light-exiting surface. The low refractive index layer 21 adjoins the high refractive index layer 22. The protective layer 10 is disposed between the low refractive index layer 21 and the light-exiting surface. An uneven structure 20 including a plurality of protrusions 23 each having two or more steps is provided at an interface between the high refractive index layer 22 and the low refractive index layer 21. In the following description, the high refractive index layer 22 corresponds to the first layer and may be referred to as a first layer 22. Moreover, the low refractive index layer 21 corresponds to the second layer and may be referred to as a second layer 21.

Regarding the organic EL element 1, relationships expressed as n₀<n₁ and n₂<n₁ are satisfied, where n₀ is the refractive index of the atmosphere, n₁ is the refractive index of the protective layer 10, and n₂ is the refractive index of the low refractive index layer (second layer) 21.

The organic EL element 1 includes the protrusions 23 each having a two or more-stepped protrusion and has the refractive indices having the relationships described above, and thereby, the direction of light becomes more likely to change. When the direction of light changes, the light-outcoupling efficiency increases for wide-angle light, and the direction of light is more likely to be directed to the front. As a result, the amount of light emitted outside can be increased, which improves the light-outcoupling efficiency.

In FIG. 1, emitted light is denoted with an outlined arrow. A light emission direction is the same as the direction denoted by the outlined arrow. The light-exiting surface is a surface of the organic EL element directed in a direction pointed out by the outlined arrow. A direction from the light emitting layer 41 toward the protective layer 10 corresponds to a direction in which the light-exiting surface is directed.

In the example illustrated in FIG. 1, the organic EL element 1 includes a light transmissive electrode 30 and a light reflective electrode 50. The light transmissive electrode 30 and the light reflective electrode 50 serve as a pair of electrodes. One of the light transmissive electrode 30 and the light reflective electrode 50 serves as an anode and the remaining electrode serves as a cathode. For example, the light transmissive electrode 30 may be an anode, and the light reflective electrode 50 may be a cathode. The light transmissive electrode 30 can be made of an electrode material having light transmissivity. The light transmissive electrode 30 may be made of, for example, a metal oxide. Examples of the metal oxide include ITO. The light reflective electrode 50 can be made of, for example, an electrode material having light reflectivity. The light reflective electrode 50 may be made of, for example, metal. Examples of the metal include Ag and Al. The light reflective electrode 50 serves as a reflective layer R1 which reflects light. The light reflective electrode 50 may be replaced with an electrode having light transmissivity, and a reflective layer R1 may be separately formed on the electrode.

In the example in FIG. 1, the organic EL element 1 includes a charge transfer layer 42 and a charge transfer layer 43. The charge transfer layer 42, the light emitting layer 41, and the charge transfer layer 43 together are collectively defined as an organic layer 40. The organic EL element 1 includes at least one organic layer 40 disposed between the pair of electrodes. The organic layer 40 serves as a light emitting unit. The light emitting unit refers to a layered structure which emits light when the layered structure is disposed between an anode and a cathode and a voltage is applied between the anode and the cathode. The light emitting layer 41 may be a single layer or a stack including two or more layers. The charge transfer layer 42 and the charge transfer layer 43 each have a function of transferring at least either holes or electrons. The charge transfer layer, which is disposed closer to the anode than the light emitting layer 41 is, may be formed as a hole transport layer. A hole injection layer may be further provided between the hole transport layer and the anode. The charge transfer layer, which is closer to the cathode than the light emitting layer 41 is, may be formed as an electron transport layer. An electron injection layer may be further provided between the electron transport layer and the cathode. FIG. 1 shows an example including one light emitting unit, but two or more light emitting units may be provided. An interlayer may be disposed between the light emitting units adjacent to each other. The organic layer 40, the light transmissive electrode 30, and the light reflective electrode 50 are collectively defined as an organic light emitting body.

The thickness of the light transmissive electrode 30 is not limited particularly, but may be, for example, within a range of 10 nm to 500 nm. The thickness of the light reflective electrode 50 is not limited particularly, but may be, for example, within a range of 10 nm to 500 nm. The thickness of the charge transfer layer 43 is not limited particularly, but may be, for example, within a range of 0 nm to 500 nm. The organic EL element 1 does not have to include the charge transfer layer 43. The thickness of the charge transfer layer 42 is not limited particularly, but may be, for example, within a range of 0 nm to 500 nm. The organic EL element 1 does not have to include the charge transfer layer 42. The thickness of the organic layer 40 is not limited particularly, but may be, for example, within a range of 20 nm to 2000 nm.

In the example of FIG. 1, the protective layer 10 serves as a substrate S1. The protective layer 10 protects the organic light emitting body. The plurality of layers included in the organic EL element 1 may be formed on the substrate S1 as a supporting substrate. The protective layer 10 may be made of glass or resin. Glass is excellent in suppressing immersion of water. Resin may provide flexibility to the organic EL element 1. The protective layer 10 preferably has light transmissivity. The protective layer 10 has a larger refractive index than the atmosphere. An adhesive layer may be provided between the protective layer 10 and the low refractive index layer 21 to improve the adhesiveness at an interface between the protective layer 10 and the low refractive index layer 21. It has been confirmed that the adhesive layer does not affect the light-outcoupling efficiency.

On the substrate S1, the low refractive index layer 21 and the high refractive index layer 22 are disposed in this order. The low refractive index layer 21 has a smaller refractive index than the substrate S1. The high refractive index layer 22 has a larger refractive index than the substrate S1. The uneven structure 20 is provided between the low refractive index layer 21 and the high refractive index layer 22. The uneven structure 20 is formed at the interface between the low refractive index layer 21 and the high refractive index layer 22. The uneven structure 20 may have a function of changing the direction of light. The uneven structure 20 may have a light scattering function. The uneven structure 20 may increase the amount of light entering the substrate S1, thereby increasing the light-outcoupling efficiency.

When a voltage is applied between the light transmissive electrode 30 and the light reflective electrode 50, light is produced in the light emitting layer 41. The light produced in the light emitting layer 41 emerges outside through the protective layer 10. The protective layer 10 serves as the substrate S1. The example of FIG. 1 has a bottom emission structure. The light may be radially generated in the light emitting layer 41. Some of rays of the light produced in the light emitting layer 41, which travel directly toward the protective layer 10, sequentially pass through the charge transfer layer 42, the light transmissive electrode 30, the high refractive index layer 22, the low refractive index layer 21, and the protective layer 10 and finally emerge outside. Some of rays of the light produced in the light emitting layer 41, which travel toward the light reflective electrode 50, pass through the charge transfer layer 43 and reach the light reflective electrode 50, and is then reflected off the light reflective electrode 50 to travel toward the protective layer 10. The reflected light passes through the light emitting layer 41, follows the light traveling directly to the protective layer 10, and then emerges outside.

Regarding the organic EL element 1, relationships expressed as n₁<n₃ and n₁<n₄ are preferably satisfied, wherein n₃ is the refractive index of the high refractive index layer (first layer) 22, and n₄ is the refractive index of the light emitting layer 41. The organic EL element 1 has the refractive indices having the relationships described above, and thereby, the direction of light becomes much more likely to change, the light-outcoupling efficiency of the wide-angle light increases, and the direction of light is more likely to be directed to the front. As a result, the amount of light emitted outside can be increased, thereby further increasing the light-outcoupling efficiency.

In the example of FIG. 1, the refractive index of the substrate S1 is equal to the refractive index of the protective layer 10 and is denoted by n₁. Thus, the relationship expressed as n₀<n₁ holds true between the refractive index n₀ of the atmosphere and the refractive index n₁ of the substrate S1. Similarly, the relationships expressed as n₂<n₁, n₁<n₃, and n₁<n₄ hold true. The relationship expressed as n₂<n₃ holds true between the low refractive index layer 21 and the high refractive index layer 22.

In general, the refractive index n₀ of the atmosphere is 1. Here, in general, the refractive index of layers of the organic EL element 1 is larger than the refractive index of the atmosphere. Therefore, in general, the relationships expressed as n₀<n₂, n₀<n₃, and n₀<n₄ hold true. However, as described later, the low refractive index layer 21 may be hollow, and in that case, the equation n₀=n₂ can hold true.

The above-described relationships of the refractive indices increase the amount of light entering the substrate S1, thereby increasing the light-outcoupling efficiency. In particular, lowering the refractive index of the low refractive index layer 21 is very effective. It has been experimentally confirmed that external quantum efficiency can be increased by 22% when the refractive index of the low refractive index layer 21 is lowered, for example, from 1.45 to 1.34.

The charge transfer layer 42 and the light transmissive electrode 30 are disposed between the light emitting layer 41 and the high refractive index layer 22, but it has been confirmed that the refractive indices of the charge transfer layer 42 and the light transmissive electrode 30 have almost no influence on the light-outcoupling efficiency. The relationship between the refractive index n₃ of the high refractive index layer 22 and the refractive index n₄ of the light emitting layer 41 may be n₃<n₄ or n₄<n₃.

The refractive index n₂ of the low refractive index layer 21 may be, for example, within a range of 1.0 to 1.5. The refractive index n₂ of the low refractive index layer 21 may be less than or equal to 1.4. The refractive index n₂ of the low refractive index layer 21 may be less than or equal to 1.3. The refractive index n₃ of the high refractive index layer 22 may be, for example, within the range of 1.5 to 2.5. The refractive index n₁ of the protective layer 10 may be, for example, within the range of 1.3 to 2.0. The refractive index n₄ of the light emitting layer 41 may be, for example, within the range of 1.5 to 2.5. The above-described refractive indices are mere examples.

The difference between refractive indices of the layers is not limited particularly, but may be set, for example, as described below. The difference between the refractive index of the refractive index n₁ of the protective layer 10 and the refractive index n₃ of the low refractive index layer 21 is preferably greater than or equal to 0.05, more preferably greater than or equal to 0.1, and further preferably greater than or equal to 0.15. The difference between the refractive index of the refractive index n₁ of the protective layer 10 and the refractive index n₃ of the high refractive index layer 22 is preferably greater than or equal to 0.05, more preferably greater than or equal to 0.1, and further preferably greater than or equal to 0.15. A maximum difference between the refractive indices is not particularly limited, but a too large difference between the refractive indices may complicate element design. Therefore, the difference between refractive indices is in any case preferably less than or equal to 1.5, and more preferably less than or equal to 1.0.

Optical measurement using, for example, a hemispherical prism can confirm that in the organic EL element 1, the refractive index n₂ of the low refractive index layer 21 is smaller than the refractive index n₁ of the protective layer 10. For example, a hemispherical prism is adhered to an outer side of the protective layer 10 with an optical adhesive, and a laser beam is allowed to enter the hemispherical prism. At this time, when a relationship expressed as n₂<n₁ holds true, varying the laser incident angle may cause total reflection. When the reflected light intensity is monitored, the reflectance is almost 100% at the occurrence of the total reflection. In this way, the relationship expressed as n₂<n₁ can be confirmed in a produced organic EL element 1. A method for confirming the refractive index is not limited to the above-described method which is only an example.

In the example of FIG. 1, the uneven structure 20 includes the protrusions 23. Each protrusion 23 is defined as a part of the low refractive index layer 21 protruding toward the high refractive index layer 22. Each protrusion 23 has a step shape. Each protrusion 23 has at least two steps. The low refractive index layer 21 may have a recess 24. The recess 24 is a part of the low refractive index layer 21 recessed toward the protective layer 10. The recess 24 may include a plurality of recesses or may be one continuous recess. From another perspective, the recess 24 may be recessed to form two or more steps. From still another perspective, the recess 24 may receive a protrusion 23a of the high refractive index layer 22. The protrusion 23a in this case is a part of the high refractive index layer 22 protruding toward the low refractive index layer 21. The protrusion 23a protrudes to form two or more steps. Similarly, the protrusions 23 may be fitted into recesses 24a in the high refractive index layer 22. Each recess 24a in this case is a part of the high refractive index layer 22 recessed in a direction toward the light transmissive electrode 30. Each recess 24a may be recessed to form two or more steps. The recesses 24a may be continuously formed into one recess. In this case, the uneven structure 20 is considered to include a plurality of protrusions 23a. As described above, the plurality of protrusions forming the uneven structure 20 may be the protrusions 23 of the low refractive index layer 21 or the protrusions 23a of the high refractive index layer 22. For simplicity of illustration, the plurality of protrusions forming the uneven structure 20 is hereinafter the plurality of protrusions 23 unless otherwise indicated, but the configuration of the protrusions 23 is applicable to the protrusions 23a.

Each protrusion 23 has a step shape. In the example of FIG. 1, each protrusion 23 has two steps. Each recess 24 can be said to be recessed to form steps. Each protrusion 23 can be said to have a shoulder part. Each protrusion 23 can be said to have a narrow part. The step of each protrusion 23 is defined as a step portion 25. The step portion 25 defines a periphery of the protrusion 23. A first-step protrusion of the protrusion 23 is the step portion 25, and a second-step protrusion of the protrusion 23 is a top end of the protrusion 23. Each recess 24 can be said to be a base part. In the example of FIG. 1, the second-step protrusion is an uppermost step. Providing the step portion 25 may effectively change the direction of light, thereby increasing the light-outcoupling efficiency.

In the uneven structure 20, each protrusion 23 has, in its thickness direction, three regions, that is, a high part 20H located at the top end of each protrusion 23, a low part 20L located at the bottom of the recess 24, and a middle part 20C located at the step portion 25. The uneven structure 20 has three positions in its thickness direction. The number of the positions in the thickness direction at the interface between the low refractive index layer 21 and the high refractive index layer 22 is defined as the number of levels. The thickness direction refers to a direction in which layers of the organic light emitting body are stacked. The example of FIG. 1 has three levels. The low part 20L is a part close to the protective layer 10. The low part 20L may have a flat surface. The high part 20H is a part close to the light transmissive electrode 30. The high part 20H may have a flat surface. The middle part 20C is located between the high part 20H and the low part 20L. The middle part 20C may have a flat surface. When each protrusion 23 has two or more steps, the number of levels is three or more.

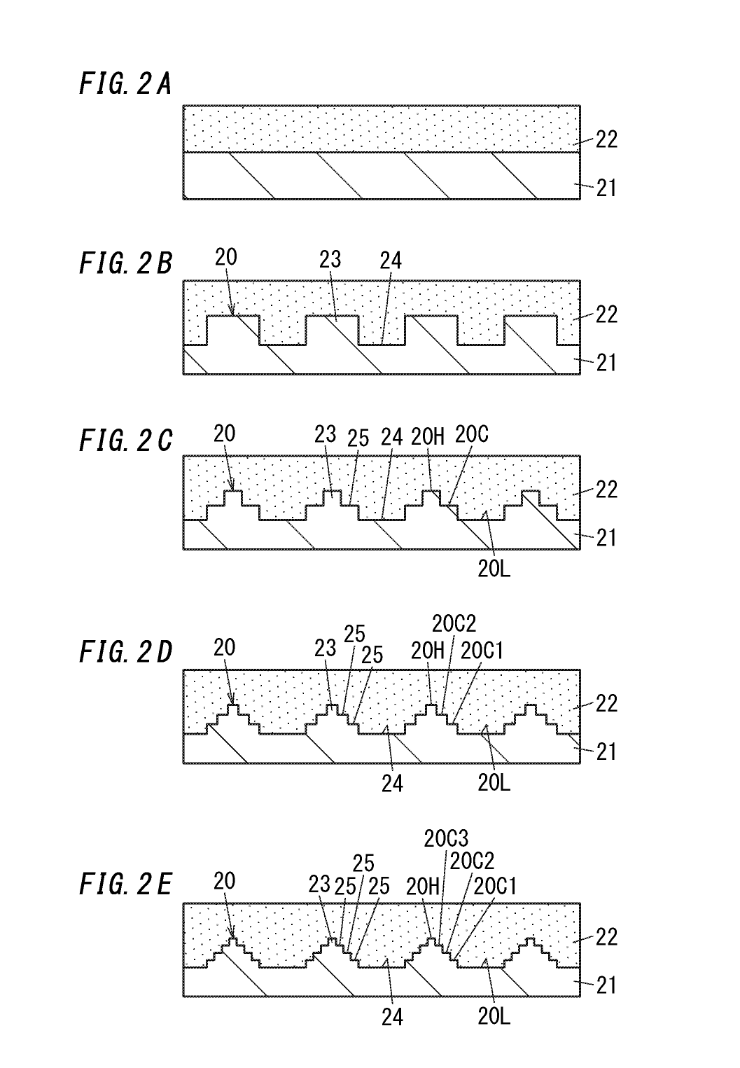

FIGS. 2A to 2E are views for illustrating the interface at which the uneven structure 20 is provided. FIGS. 2A to 2E show only a stack of the low refractive index layer 21 and the high refractive index layer 22 of the organic EL element 1. As illustrated in FIGS. 2C to 2E, each protrusion 23 of the organic EL element 1 has at least two steps. The protrusion 23 may have three or more steps or four or more steps. With reference to FIGS. 2A to 2E, the number of levels will be described.

As illustrated in FIG. 2A, when no uneven structure 20 is provided, the number of levels is one. There is only one interface in the thickness direction. As illustrated in FIG. 2B, when the uneven structure 20 has protrusions 23 each having one step, the number of levels is two. There are two interfaces in the thickness direction. As illustrated in FIG. 2C, when the uneven structure 20 has protrusions 23 each having two steps, the number of levels is three. There are three interfaces in the thickness direction. As illustrated in FIG. 2D, when the uneven structure 20 has protrusions 23 each having three steps, the number of levels is four. There are four interfaces in the thickness direction. As illustrated in FIG. 2E, when the uneven structure 20 has protrusions 23 each having four steps, the number of levels is five. There are five interfaces in the thickness direction. As described above, when the uneven structure 20 is provided, the number of levels is equal to the number obtained by adding one to the number of steps. The number obtained by adding two to the number of step portions 25 can be said to be the number of levels. A case where the number of levels is greater than or equal to six will also be understood in a similar manner. The protrusions 23 each having two steps illustrated in FIG. 2C are applied to the aspect of FIG. 1. The protrusions 23 illustrated in FIG. 2D and FIG. 2E may be applied to the aspect of FIG. 1. The high part 20H, the low part 20L, and the middle part 20C are as described above and are illustrated in FIGS. 2C to 2E. When the step portion 25 includes two or more step portions, middle parts 20C may be referred to as a first middle part 20C1, a second middle part 20C2, and a third middle part 20C3 in this order from the low refractive index layer 21. As in this case, a plurality of middle parts 20C may be provided.

Each protrusion 23 is only required to have a step shape, and the height of each step is not particularly limited. The height of each step means a length in the thickness direction. Each protrusion 23 may have steps having the same height. This can efficiently increase the light-outcoupling efficiency. In a case of each protrusion 23 having two steps, the step portion 25 may be located at a middle between the bottom of the recess 24 and the top end of the protrusion 23 in the thickness direction. In a case of each protrusion 23 having three steps, the step portions 25 may be located at positions of ⅓ and ⅔ of the height of the protrusion 23. Steps of each protrusion 23 may be provided at a regular interval. The same applies to the middle parts 20C formed by the step portions 25.

The plurality of protrusions 23 may have an identical shape. The protrusions 23 having an identical shape can easily increase the light-outcoupling efficiency. The uneven structure 20 may have a structure in which the low refractive index layer 21 does not exist at the bottom of each recess 24. At the bottom of each recess 24, the high refractive index layer 22 may be in contact with the protective layer 10. The uneven structure 20 may have a structure in which the high refractive index layer 22 does not exist at the top end of each protrusion 23. At the top end of each protrusion 23, the low refractive index layer 21 may be in contact with the light transmissive electrode 30.

The organic EL element 1 preferably includes the reflective layer R1, which reflects light, provided on an opposite side of the light emitting layer 41 from the light exiting side. In the example of FIG. 1, the light reflective electrode 50 serves as the reflective layer R1. The reflective layer R1 causes reflection of light, thereby increasing the amount of light traveling in the reflection direction. A relationship expressed as L₁≧λ/(3n₅) is preferably satisfied, where n₅ is the refractive index of a medium between the reflective layer R1 and the light emitting layer 41, which is a light emitting layer located closest to the reflective layer R1, λ is the wavelength of light produced in the light emitting layer 41, and L₁ is the distance between the light emitting layer 41 and the reflective layer R1.

When the distance between the light emitting layer 41 and the reflective layer R1 satisfies the above-described relationship, plasmon can be reduced, which allows extraction of more light to the outside. The plasmon causes loss of light generated in the light emitting layer 41 on the surface of the reflective layer R1 due to energy absorption when the light is reflected off the surface of the reflective layer R1. The plasmon may occur in particular at the surface of a metal layer. The distance between the light emitting layer 41 and the reflective layer R1 is increased to effectively reduce the plasmon. The wavelength λ of light of the light emitting layer 41 and the refractive index n₅ of the medium between the light emitting layer 41 and the reflective layer R1 may relate to plasmon suppression. The medium is a substance filling a space. The distance L₁ greater than or equal to λ/(3×n₅) effectively suppresses the plasmon. The unit for the distance L₁ may be nm. In FIG. 1, the light emitting layer 41 is a light emitting layer located closest to the reflective layer R1. However, when two or more light emitting layers are provided, one of the light emitting layers which is located closest to the reflective layer R1 is the light emitting layer of this case. For simplicity of illustration, the light emitting layer 41 is hereinafter deemed to be the light emitting layer located closest to the reflective layer R1.

An upper limit of the distance L₁ is not particularly specified, but when the distance L₁ is too large, element design may be complicated. In this respect, the distance L₁ preferably satisfies a relationship expressed as L₁<λ, and more preferably satisfies a relationship expressed as L₁<λ/2. A relationship expressed as L₁<λ/n₅ is also preferable. A relationship expressed as L₁<λ/3 may hold true. Specifically, the distance L₁ can be, for example, within a range of 50 nm to 500 nm.

The wavelength λ represents the wavelength of light produced in the light emitting layer 41. The wavelength λ is obtained by calculating a weighted average of the spectrum of light expressed using a horizontal axis representing the wavelength and a vertical axis representing the relative intensity. The wavelength λ is generally within the visible light region. The wavelength λ may be within the range of 400 nm to 700 nm. The wavelength λ may be, for example, 500 nm to 600 nm. The refractive index n₅ represents the averaged refractive index of media between the light emitting layer 41 and the reflective layer R1. When the charge transfer layer 43 includes a single layer, the charge transfer layer 43 has the refractive index n₅. When the charge transfer layer 43 includes two or more layers, the refractive indices of the layers are weighted with the thicknesses of the layers and averaged to obtain the refractive index n₅. The refractive index n₅ may be, for example, within a range of 1.5 to 2.5.

Increasing the distance L₁ between the light emitting layer 41 and the reflective layer R1 is advantageous for the plasmon suppression but may increase the amount of wide-angle light. The wide-angle light means light entering the substrate S1 obliquely at a relatively large incident angle. The incident angle is an angle between a direction of light and a line (normal) in a direction perpendicular to the surface of the substrate S1. The wide angle may mean an incident angle of greater than or equal to 40 degrees. The wide-angle light is likely to undergo total reflection at the substrate S1 (protective layer 10). Extracting the wide-angle light leads to an increase in total light-outcoupling efficiency. Each protrusion 23 of the organic EL element 1 has two or more steps, so that more wide-angle light can be extracted. Thus, the wide-angle light due to the plasmon suppression can be effectively extracted.

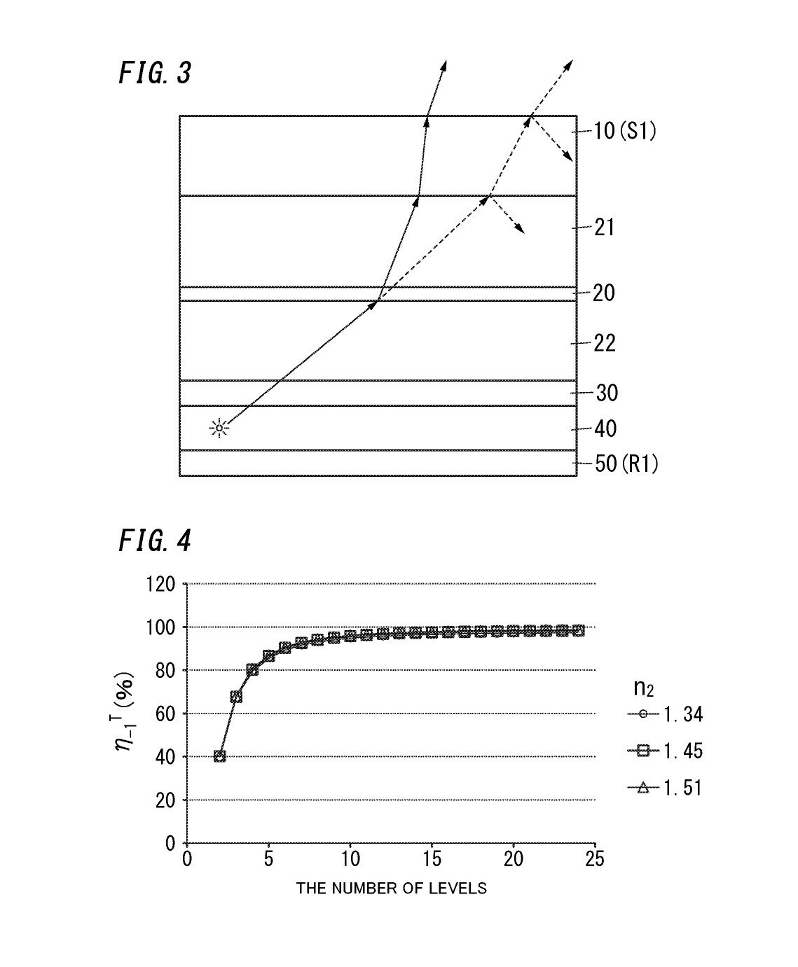

FIG. 3 is a schematic diagram illustrating traveling of light of the organic EL element. In FIG. 3, the order of layers is illustrated upside down compared to that in FIG. 1, and light is emitted upward. FIG. 3 shows a model, and the thicknesses of layers are not to scale. Arrows represent traveling of light.

Light produced in the light emitting layer 41 includes many components traveling not only in a direction perpendicular to the surface of the substrate S1 but also in a direction oblique to the direction perpendicular to the surface of the substrate S1. With reference to FIG. 3, traveling of light in a direction oblique to the surface of the substrate S1 will be described. Obliquely traveling light includes light directly traveling from a light emitting source and light reflected off the reflective layer R1. The light emitting source is provided in the light emitting layer 41.

As illustrated in FIG. 3, the obliquely traveling light goes out of the organic layer 40, passes through the light transmissive electrode 30, and then enters the high refractive index layer 22. Here, since the refractive indices of the light emitting layer 41, the light transmissive electrode 30, and the high refractive index layer 22 are adjusted to reduce differences therebetween, the Fresnel reflection of the high refractive index layer 22 may be reduced. For example, the absolute value of a difference between refractive indices of the high refractive index layer 22 and the light emitting layer 41 is preferably less than or equal to 0.5 and more preferably less than or equal to 0.1. The absolute value of a difference between refractive indices of, for example, the light transmissive electrode 30 and the light emitting layer 41 is preferably less than or equal to 0.5 and more preferably less than or equal to 0.1. The absolute value of a difference between refractive indices of, for example, the high refractive index layer 22 and the light transmissive electrode 30 is preferably less than or equal to 0.5 and more preferably less than or equal to 0.1. Matching the refractive indices with each other as described above reduces the Fresnel reflection.

Light which entered the high refractive index layer 22 reaches the uneven structure 20. In FIG. 3, the uneven structure 20 is shown as a layer, but as illustrated in FIG. 1, the uneven structure 20 may be formed at the interface between the high refractive index layer 22 and the low refractive index layer 21. The uneven structure 20 includes the plurality of protrusions 23, which allows the direction of light to be changed. The protrusions 23 each having two or more steps enhance the effect of changing the direction of light to a lower angle, that is, to approach the normal of the substrate S1. This effect is caused by an increase in the efficiency of −1-order transmission diffraction light. This effect can cause rays of light ray to travel upright relative to the substrate. The protrusions 23 each having two or more steps allow more wide-angle light to be extracted. The steps provided between the protrusion 23 and the recess 24 may effectively change the direction of obliquely traveling light. When the protrusions 23 each have two or more steps, the obliquely traveling light is more likely to be incident on side portions of the protrusions 23. As described above, providing the uneven structure 20 including protrusions 23 each having two or more steps enables more light to be extracted. The uneven structure 20 may serve as a diffraction lattice surface.

The −1-order transmission diffraction light is first light whose direction is changed toward an outer side due to diffraction. Zero-order transmission diffraction light is a component traveling straight. Transmitted light undergoes 0-order diffraction, −1-order diffraction, −2-order diffraction, −3-order diffraction . . . . In FIG. 3, the solid line shows the −1-order transmission diffraction light of light passed through the uneven structure 20, and the broken line shows the 0-order transmission diffraction light.

FIG. 4 is a graph illustrating an example relationship between the number of levels of the uneven structure 20 and the efficiency η₋₁^{T} of the −1-order transmission diffraction light. As previously described, the number of levels may be a value obtained by adding one to the number of steps of the protrusion 23. As the number of levels increases, the efficiency η₋₁^{T} of the −1-order transmission diffraction light increases, and the direction of light may be changed toward the normal of the substrate S1. According to the scalar theory (complex transmittance distribution approximation), the efficiency of the −1-order transmission diffraction light may be given by the following expression in any polarization state.

$${η}_{- 1} T = \frac{4 {n}_{low} {n}_{high}}{{( {n}_{low} + {n}_{high} )}^{2}} \times {( \frac{sin ( π / M )}{π / M} )}^{2} \qquad [ Formula 1 ]$$

In the above expression, M is the number of levels, n_{low} is the refractive index of the low refractive index layer, and n_{high} is the refractive index of the high refractive index layer. With this expression, the graph of FIG. 4 is obtained.

As illustrated in the graph of FIG. 4, when the number of levels is two, that is, the uneven structure 20 includes protrusions 23 each having one step, the efficiency η₋₁^{T} of the −1-order transmission diffraction light is lower than 50%, and the efficiency η₋₁^{T} of the −1-order transmission diffraction light is not very high. However, when the number of levels is greater than or equal to three, that is, when the protrusions 23 each have two or more steps, the efficiency η₋₁^{T} of the −1-order transmission diffraction light is greater than 60%. Thus, providing the protrusions 23 each having two or more steps allows the direction of light to approach the front. Thus, the light-outcoupling efficiency can be increased. The greater the number of levels, the higher the efficiency η₋₁^{T} of the −1-order transmission diffraction light. Note that the larger the number of levels, the smaller the degree of increase. For ease of formation of steps of each protrusion 23, six or less levels (less than or equal to five steps) are preferable, and five or less levels (less than or equal to four steps) are more preferable. Each protrusion 23 may have three or less steps or may have two steps. In FIG. 4, the refractive index n₂ of the low refractive index layer 21 is changed. As illustrated in FIG. 4, the change in the refractive index n₂ of the low refractive index layer 21 has almost no influence on the change in the efficiency η₋₁^{T} of the −1-order transmission diffraction light due to an increase and a decrease in the number of levels.

As illustrated in FIG. 3, light which passed through the uneven structure 20 enters the low refractive index layer 21 and reaches the interface between the low refractive index layer 21 and the protective layer 10. At this time, the refractive index of the protective layer 10 is larger than the refractive index of the low refractive index layer 21, and therefore, the direction of the light entered the protective layer 10 may be changed to a lower angle, that is, to approach the normal of the substrate S1. Further, the incident angle to the interface decreases, thereby reducing the Fresnel loss. Then, the light passes through the protective layer 10 and is output to an outer side where the atmosphere exists. Since the atmosphere is lower in refractive index than the protective layer 10, the direction of the light may change to a direction with a larger angle. The direction of light may be inclined to reduce an angle relative to the substrate. When the light travels obliquely at an angle large enough to exceed the critical angle, total reflection occurs, leading to light confined in the protective layer 10. Here, as described above, the direction in which light travels in the organic EL element 1 tends to change easily to a direction in which light travels upright relative to the substrate before the light reaches the interface between the protective layer 10 and the atmosphere. This structure can also reduce the Fresnel loss. Thus, the total reflection at the interface between the protective layer 10 and the atmosphere is suppressed, thereby increasing the light-outcoupling efficiency.

In view of the above results, it can be said that adjusting the refractive index of the low refractive index layer 21 to be lower than that of the protective layer 10 has an advantage of facilitating control of the direction of light rays, a reduction in Fresnel reflection along with the control, and light extraction at the interface. By contrast, a trade-off relationship may occur in which a light-outcoupling structure having one or less step increases the refractive index contrast between the low refractive index layer 21 and the high refractive index layer 22, which results in that total reflection is easily caused and the extraction efficiency of wide angle components is reduced.

Therefore, as previously described, when a multilevel structure (uneven structure including two or more steps) is used, an increase in light-outcoupling efficiency in a wide angle and an effect of controlling the direction of light rays by an increase in −1-order diffraction component may ease the trade-off relationship due to the reduced refractive index.

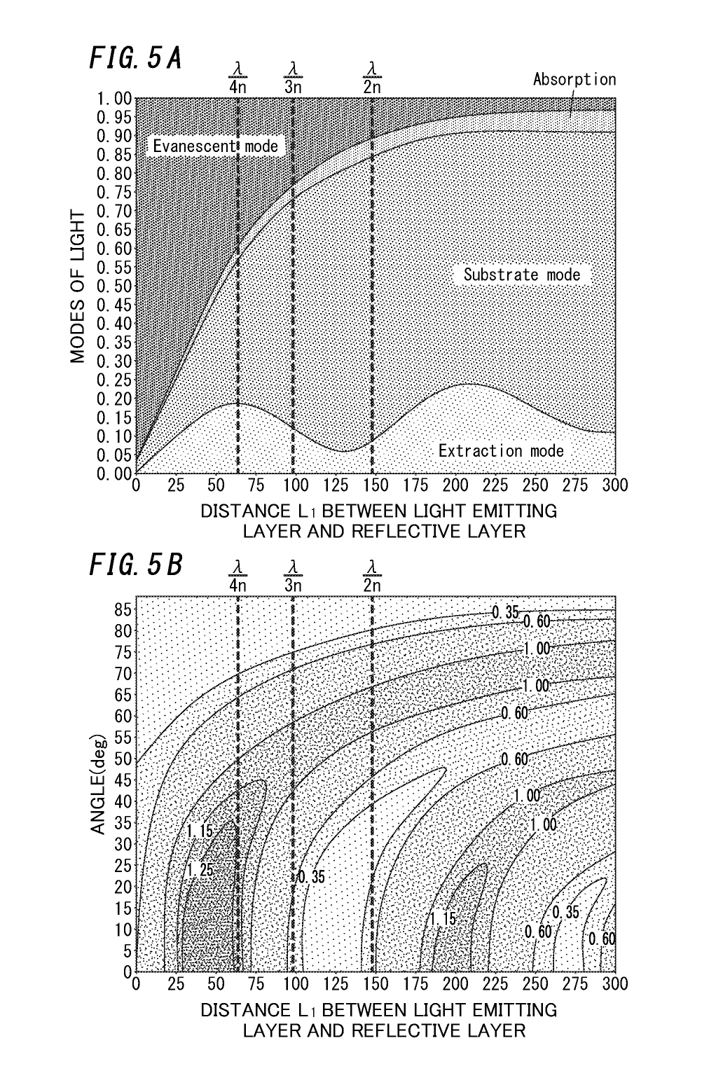

FIGS. 5A and 5B are graphs illustrating changes caused by varying the distance L₁ between the light emitting layer 41 and the reflective layer R1. FIG. 5A is a graph illustrating the relationship between the distance L₁ and the modes of light. FIG. 5B is a graph illustrating the relationship between the distance L₁ and the angle of light to be extracted (the angle between the normal of the substrate S1 and the light to be extracted). In FIG. 5B, the intensity of light is relativized and is illustrated in a contour-line pattern.

As illustrated in FIG. 5A, light is classified into an Evanescent mode, Absorption, a Substrate mode, and an Extraction mode. Among these modes, the Evanescent mode is a region where plasmon occurs. The substrate mode is a region where light is confined due to total reflection at a substrate surface. The Absorption is a region where light is lost due to absorption by materials. The extraction mode is a region where light is extracted outside. The amount of light in the extraction mode may increase or decrease when the distance L₁ is varied because the interference action of light changes. Therefore, the border between the extraction mode and the substrate mode is in a wave shape.

The graph in FIG. 5A shows that when the distance L₁ is small, a large amount of light is distributed in the Evanescent mode. It can be understood that when the distance L₁ exceeds λ/(4n₅), the amount of light in the Evanescent mode decreases, and when the distance L₁ exceeds λ/(3n₅), the amount of light in the Evanescent mode further decreases. Therefore, in order to suppress plasmon, the distance L₁ is preferably greater than or equal to λ/(3n₅). From the graph, it could be understand that to reduce plasmon, the distance L₁ is preferably greater than or equal to λ(2n₅).

The graph in FIG. 5B shows that when the distance L₁ is small, the amount of light at a small angle is large. The light at a small angle can be easily emitted outside. However, as the distance L₁ increases, the amount of light at a large angle increases. In particular, when the L₁ is greater than or equal to λ/(3n₅) in order to suppress plasmon, components having a large angle increase. As described above, the distance L₁ is preferably increased in order to suppress plasmon, but when the distance L₁ is increased, wide angle components increases. Thus, the uneven structure 20 having protrusions 23 each having a two or more steps allows the wide angle components to be more effectively extracted and is thus advantageous. Of course, when the L₁ is less than λ/(3n₅), the uneven structure 20 having a step shape is excellent in light-outcoupling efficiency. In FIGS. 5A and 5B, n₅ representing the refractive index is simply indicated as n.

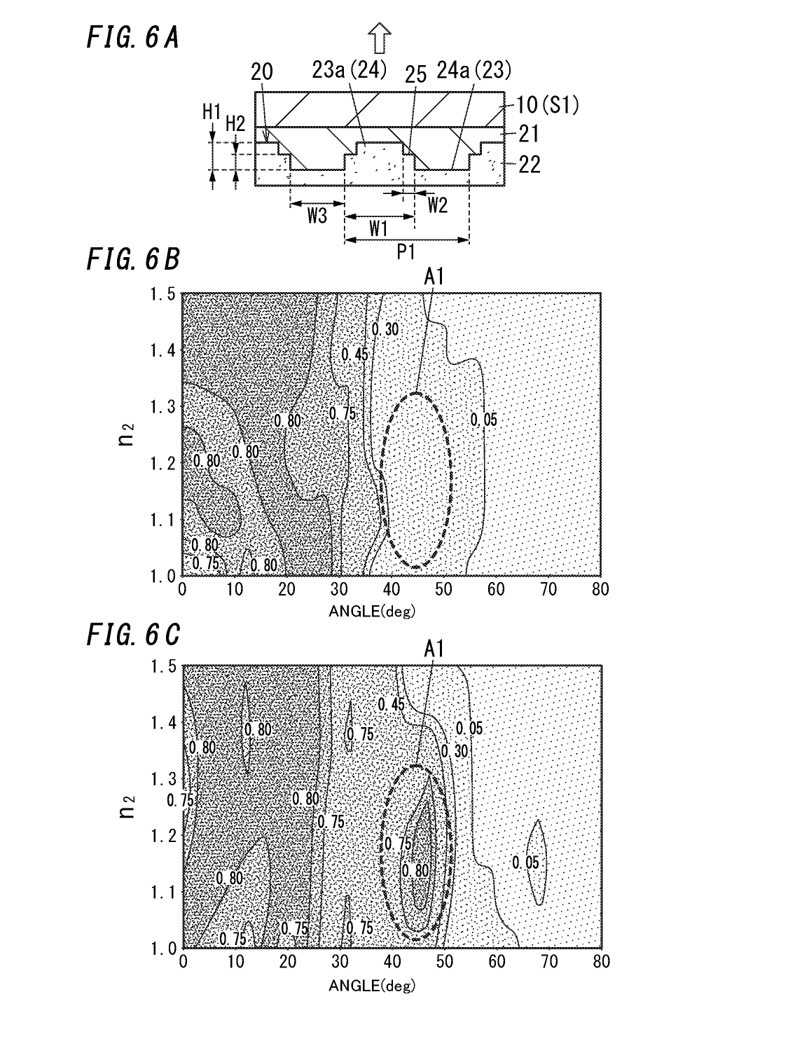

FIGS. 6A to 6C show an example illustrating a simulation result of the relationship between the light-outcoupling efficiency and the number of steps of the protrusion 23. FIG. 6A is a model of the uneven structure 20. FIG. 6B is a graph illustrating the transmittance of light through an uneven structure 20 having protrusions 23 each having one step. FIG. 6C is a graph illustrating the transmittance of light through an uneven structure 20 having protrusions 23 each having two steps. In FIGS. 6B and 6C, the transmittance of light is illustrated in a contour-line pattern obtained by varying parameters which are the angle of the light and the refractive index n₂ of the low refractive index layer 21. The transmittance in the graphs of FIGS. 6B and 6C shows the ratio of light emitted outside through the substrate S1 (the protective layer 10) with respect to light produced in the light emitting layer 41. When each protrusion 23 has two or more steps, the uneven structure 20 may be referred to as a multilevel uneven structure 20. When each protrusion 23 has one step, the uneven structure 20 may be referred to as a single-level uneven structure 20.

A simulation is performed on the structure illustrated in FIG. 6A. In FIG. 6A, the protrusions 23a of the high refractive index layer 22 form the uneven structure 20. The protrusions 23a are disposed with a fixed period. As illustrated in FIG. 6A, the period of the protrusions 23a is denoted by P1. The overall height of each protrusion 23a is denoted by H1, and the height of the step portion 25 is denoted by H2. The height is measured from the bottom of the recess 24a of the high refractive index layer 22 in the vertical direction. The width of each protrusion 23a is denoted by W1. The width of the step portion 25 is denoted by W2. D1 is defined as the ratio of protrusions. The ratio D1 is expressed as W1/P1. The protrusions 23a are periodically arranged.

FIG. 6B shows a result of light transmittance, where the overall height H1 is 0.8 μm, the period P1 is 5.4 μm, and the ratio D1 is 0.25. Since no step is provided, the height H2 and the width W2 are not set. FIG. 6C shows a result of light transmittance, where the overall height H1 is 1.2 μm, the height H2 is 0.6 μm, the period P1 is 2.4 μm, the width W2 is 0.6 μm, and the ratio D1 is 0.8. The comparison between FIGS. 6B and 6C shows that the uneven structure 20 having the step portion 25 allows transmission of a large amount of wide angle components. The amount of transmitted wide angle components can be more likely increased when the refractive index n₂ of the low refractive index layer 21 decreases. That is, a synergistic effect of the step portion 25 and a reduction in refractive index of the low refractive index layer 21 enables extraction of wide angle components. In FIGS. 6B and 6C, a range of wide angle components is shown as an area A1. In FIG. 6C, a numerical value of the transmittance in the area A1 is higher than in FIG. 6B. As described above, the low refractive index layer 21 and the protrusions 23 each having two or more steps allow more wide-angle components to be extracted outside, which improves the light-outcoupling efficiency. Note that a maximum value of the transmittance of light can be higher in a case of the protrusions 23 each having one step, but when a large amount of wide angle components can be collected, the amount of light increases exponentially, and therefore, the protrusions 23 each having two or more steps can be advantageous to improve a total amount of light.

With reference to FIG. 6A, preferable dimensions of the uneven structure 20 will be described. The width W1 of each protrusion 23a may be within a range of 0.1 μm to 100 μm. The width W3 of the recess 24a may be within a range of 0.1 μm to 100 μm. The period P1 may be within a range of 0.1 μm to 100 μm. The width W2 of the step portion 25 may be within a range of 0.1 μm to 30 μm. The width W2 of the step portion 25 may be within a range of 10% to 40% of the width W1 of the protrusion 23a. The protrusion 23 of the low refractive index layer 21 has similar preferable dimensions.

The low refractive index layer 21 may be made of resin. The low refractive index layer 21 may include low refractive index particles. Examples of the low refractive index particles include hollow particles. Examples of the hollow particles include hollow silica fine particles.

The high refractive index layer 22 may be made of resin. The high refractive index layer 22 may include high refractive index particles. The high refractive index particles may be either organic particles or inorganic particles. For example, the high refractive index particle can be made of a titanium oxide. Moreover, the high refractive index layer 22 may be made of an inorganic layer. Examples of a material preferably used for the high refractive index layer 22 include Ti, Zr, Zn, In, Ga, Sn, Si, and oxides thereof. Moreover, examples of a material preferably used for the high refractive index layer 22 include an oxide or a nitride of Si. Examples of a material preferably used for the high refractive index layer 22 include an organic-inorganic hybrid material in which any one or more of the above-described metals, metal oxides, inorganic substances, inorganic oxides, and inorganic nitrides are dispersed. The high refractive index layer 22 may be made of a film material. The film material may be a molded product of resin. Examples of the film material include PET, PBN, PTT, PEN, and CO. Of course, these materials are mere examples, and the material of the high refractive index layer 22 is not limited to these examples.

The uneven structure 20 can be formed by an appropriate method for forming protrusions and recesses. For example, the uneven structure 20 may be formed by imprinting. Nano imprinting is shown as an example. The nano imprinting can efficiently form nanosized protrusions and recesses. The nano imprinting can easily form the protrusions 23 each having the step portion 25. In the nano imprinting, nanosized protrusions and recesses are formed on a mold, and the protrusions and recesses of the mold are transferred. The printing is thus performed. The method using the mold is preferable for formation of protrusions and recesses on the resin layer. Of course, the uneven structure 20 may be formed by a method other than the nano imprinting. For example, the uneven structure 20 can be formed by machining, laser processing, a combination of multi-stage mask exposure and dry etching, etc.

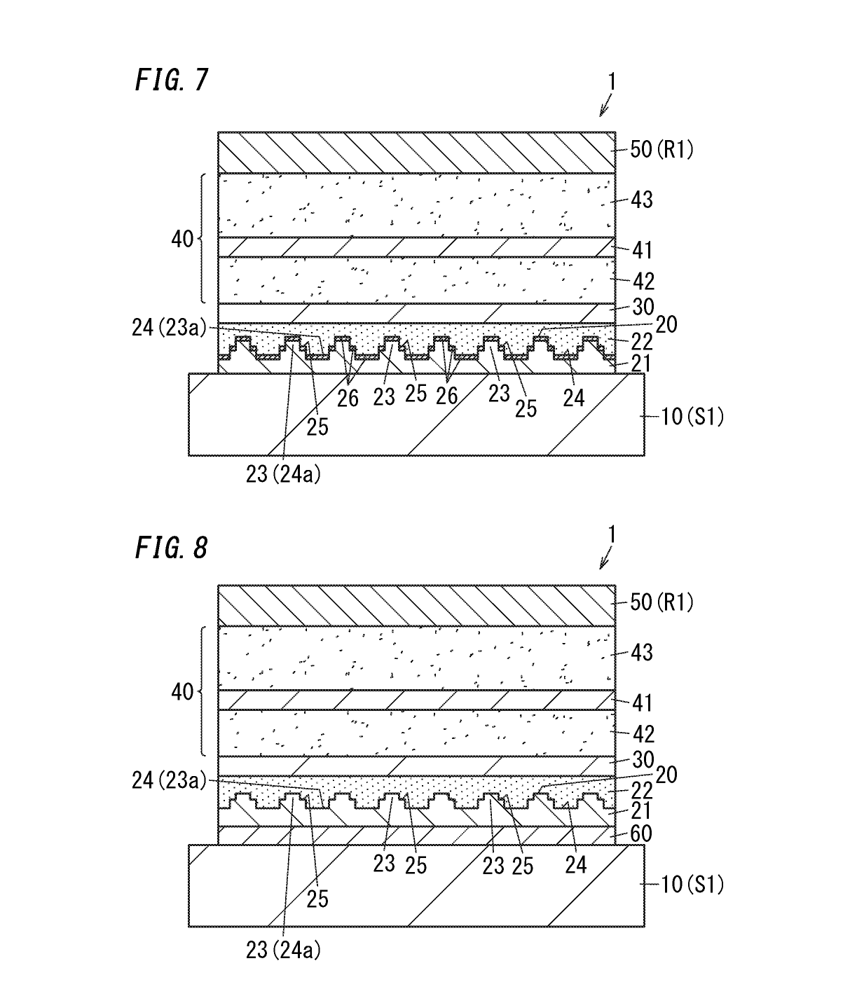

FIG. 7 shows an example of the organic EL element 1. The embodiment of FIG. 7 is a variation of the embodiment of FIG. 1 and may be the same as the embodiment of FIG. 1 except for points described below. Each member also shown in FIG. 1 is identified by the same reference sign, and the description thereof will be omitted.

In the example of FIG. 7, the uneven structure 20 includes a structure having a refractive index between the refractive index of the high refractive index layer (first layer) 22 and the refractive index of the low refractive index layer (second layer) 21. The structure having the refractive index between the refractive index of the high refractive index layer 22 and the refractive index of the low refractive index layer 21 is defined as an intermediate refractive index structure 26. The intermediate refractive index structure 26 reduces reflection at the interface which would otherwise exist between the low refractive index layer 21 and the high refractive index layer 22. This can increase the amount of light output to the outside.

The intermediate refractive index structure 26 has a refractive index between the refractive index of the low refractive index layer 21 and the refractive index of the high refractive index layer 22. A relationship expressed as n₂<n₆<n₃ holds true, where n₆ is the refractive index of the intermediate refractive index structure 26. The refractive index n₆ of the intermediate refractive index structure 26 may be higher than the refractive index n₁ of the protective layer 10. In this case, a relationship expressed as n₁<n₆ holds true. The refractive index n₆ of the intermediate refractive index structure 26 may be lower than the refractive index n₁ of the protective layer 10. In this case, a relationship expressed as n₆<n₁ holds true.

The intermediate refractive index structure 26 may be an appropriate structure which expresses a refractive index between the refractive index of the low refractive index layer 21 and the refractive index of the high refractive index layer 22. The intermediate refractive index structure 26 is provided at the interface between the low refractive index layer 21 and the high refractive index layer 22. The intermediate refractive index structure 26 is provided along the shape of the uneven structure 20. The intermediate refractive index structure 26 may be provided on surfaces of the protrusions 23, the step portions 25, and the recesses 24. The intermediate refractive index structure 26 may be formed by introduction of a layer or transformation of the structure of the low refractive index layer 21 or the high refractive index layer 22.

Examples of the intermediate refractive index structure 26 include a thin film. The thin film may have a thickness which does not impair the effect of the uneven structure 20. The thickness of the thin film is preferably less than the height of the step portion 25. The thin film may have the refractive index n₆. Examples of the intermediate refractive index structure 26 include a moss eye structure. The moss eye structure may include a plurality of protrusions smaller than the protrusions 23. Each protrusion of the moss eye structure has a size preferably smaller than the height of the step portion 25. The moss eye structure may be provided to the low refractive index layer 21 or may be provided to the high refractive index layer 22. The moss eye structure may have the refractive index n₆. Examples of the intermediate refractive index structure 26 include a plurality of protrusions formed by fine particles included in the low refractive index layer 21 or the high refractive index layer 22. In this case, a layer including the fine particles may have a surface roughness of, for example, greater than or equal to 100 nm. The surface roughness may be less than or equal to 1000 nm. A structure provided with fine protrusions may have the refractive index n₆. The surface roughness in this case may be Rz.

Here, as a difference between the refractive index of the high refractive index layer 22 and the refractive index of the low refractive index layer 21 increases, the critical angle at which the total reflection of light at the interface between these layers tends to become small. In a case of total reflection of light, extraction of the light to the outside becomes difficult. In particular, in a case of a structure which extracts wide-angle light, making the critical angle small increases the amount of light at an angle at which total reflection occurs. Therefore, in the embodiment of FIG. 7, the intermediate refractive index structure 26 is provided at the interface between the high refractive index layer 22 and the low refractive index layer 21. The intermediate refractive index structure 26 can act as if reducing the difference between the refractive index of the high refractive index layer 22 and the refractive index of the low refractive index layer 21, which can reduce the total reflection at the interface which would otherwise exist between the low refractive index layer 21 and the high refractive index layer 22. Thus, the light-outcoupling efficiency can be increased.

FIG. 8 is an example of the organic EL element 1. The embodiment of FIG. 8 is a variation of the embodiment of FIG. 1 and may be the same as the embodiment of FIG. 1 except for points described below. Each member also shown in FIG. 1 is identified by the same reference sign, and the description thereof will be omitted.

In the example of FIG. 8, a structure having a refractive index lower than that of the protective layer 10 is provided between the protective layer 10 and the low refractive index layer (second layer) 21. The structure, which has a refractive index lower than that of the protective layer 10, provided between the protective layer 10 and the low refractive index layer 21 is defined as a refractive index adjusting structure 60. The refractive index adjusting structure 60 can reduce the Fresnel reflection. This increases the amount of light output to the outside.

The refractive index adjusting structure 60 has a refractive index lower than that of the protective layer 10 (substrate S1). A relationship expressed as n₇<n₁ holds true, where n₇ is the refractive index of the refractive index adjusting structure 60. The refractive index n₇ of the refractive index adjusting structure 60 may be greater than the refractive index n₂ of the low refractive index layer 21. In this case, a relationship expressed as n₂<n₇ holds true. The refractive index n₇ of the refractive index adjusting structure 60 may be lower than the refractive index n₂ of the low refractive index layer 21. In this case, a relationship expressed as n₇<n₂ holds true.

The refractive index adjusting structure 60 may be an appropriate structure which expresses a refractive index lower than that of the protective layer 10. The refractive index adjusting structure 60 is provided between the low refractive index layer 21 and the protective layer 10. The refractive index adjusting structure 60 may be formed by introduction of a layer of by transformation of the structure of the protective layer 10 or the low refractive index layer 21.

Examples of the refractive index adjusting structure 60 include an inorganic layer and a resin layer. Examples of the material of the inorganic layer include, for example, SiO₂ and MgF. Examples of the resin layer include a layer made of resin containing a fluorine group (F group). These layers can adjust the refractive index. These layers may have the refractive index n₇. Examples of the refractive index adjusting structure 60 include a moss eye structure. The moss eye structure may include a plurality of fine protrusions. Each protrusion of the moss eye structure preferably has a size smaller than the height of the protrusion 23. The moss eye structure may be provided to the protective layer 10 or the low refractive index layer 21. The moss eye structure may have the refractive index n₇. Examples of the refractive index adjusting structure 60 include structure transformation of the protective layer 10. For example, when the protective layer 10 is a glass substrate made of soda-lime glass, deficiency of sodium at a surface of the glass substrate may result in formation of the refractive index adjusting structure 60. In soda-lime glass having a refractive index of n₁, a region deficient in sodium may have the refractive index n₇.

Here, as the difference between the refractive index of the high refractive index layer 22 and the refractive index of the low refractive index layer 21 increases, the Fresnel reflection tends to increase. In a case of an increase in Fresnel reflection, extraction of light to the outside becomes difficult. In particular, a structure which extracts wide-angle light tends to result in large Fresnel reflection. Therefore, in the embodiment of FIG. 8, the refractive index adjusting structure 60 is disposed at the interface between the protective layer 10 and the low refractive index layer 21. The refractive index adjusting structure 60 can reduce the Fresnel reflection caused due to the difference between the refractive index of the high refractive index layer 22 and the refractive index of the low refractive index layer 21. Thus, the light-outcoupling efficiency can be increased. Note that the organic EL element 1 may include both the intermediate refractive index structure 26 in the embodiment of FIG. 7 and the refractive index adjusting structure 60 in the embodiment of FIG. 8. In this case, the light-outcoupling efficiency can further be increased.

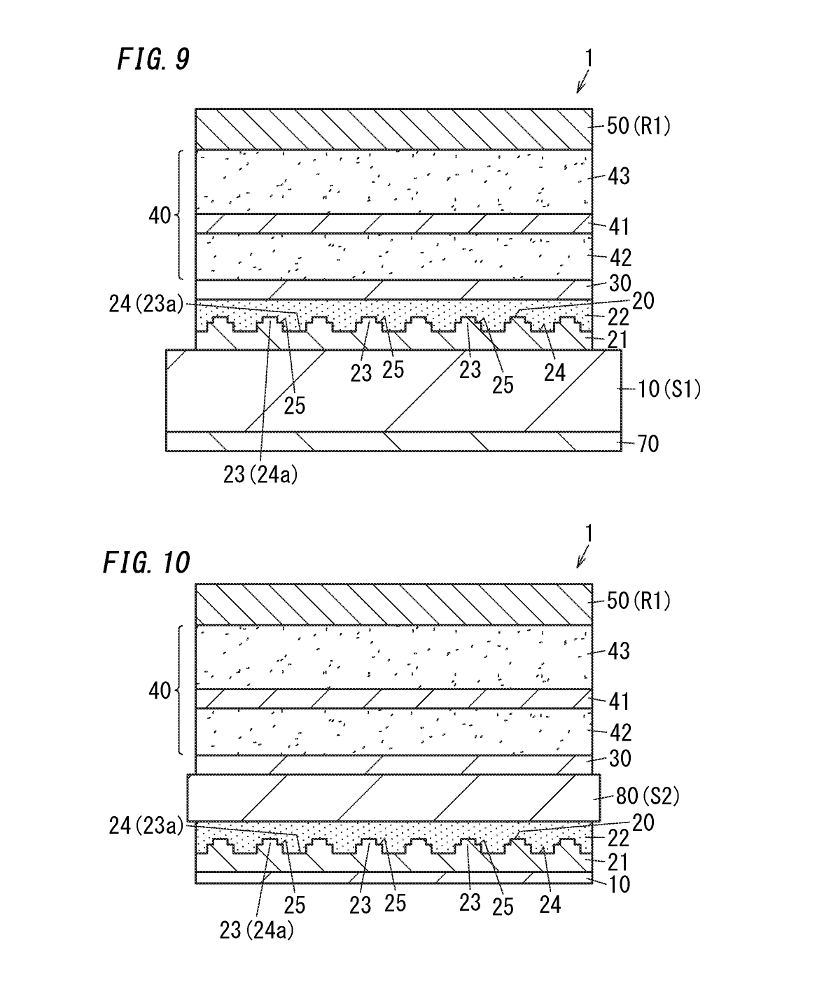

FIG. 9 shows an example of the organic EL element 1. The embodiment of FIG. 9 is a variation of the embodiment of FIG. 1 and may be the same as the embodiment of FIG. 1 except for points described below. Moreover, the embodiment of FIG. 9 may include one or both of the intermediate refractive index structure 26 described with reference to FIG. 7 and the refractive index adjusting structure 60 described with reference to FIG. 8. Each member also shown in FIG. 1 is identified by the same reference sign, and the description thereof will be omitted.

The embodiment of FIG. 9 includes a light outcoupling structure 70 between the protective layer 10 and the light-exiting surface of the organic EL element. Providing the light outcoupling structure 70 enables extraction of more amount of light toward outside through the protective layer 10.

The light outcoupling structure 70 may be an appropriate structure disposed on a surface of the substrate S1. The light outcoupling structure 70 may be a layer. Examples of the light outcoupling structure 70 include a film. The film may be a molded product of resin. The light outcoupling structure 70 can be formed easily by attaching the film. The film may include a microlens array. The film may include a diffraction grating. Moreover, the light outcoupling structure 70 may be formed of a stack of resin layers having uneven structures. For example, the uneven structure has a plurality of protrusions or recesses, thereby increasing light-outcoupling efficiency. The uneven structure may adopt a similar structure to the uneven structure 20 having a layered structure of the low refractive index layer 21 and the high refractive index layer 22 described above. For example, the high refractive index layer and the low refractive index layer in the light outcoupling structure 70 are arranged in this order in a direction in which light is output. The protrusions included in the light outcoupling structure 70 may be the same as the protrusions 23 or the protrusions 23a. The uneven structure is formed by, for example, imprinting. When in particular, an uneven structure including a plurality of protrusions each having two or more steps is adopted as the uneven structure of the light outcoupling structure 70, the light-outcoupling efficiency can be effectively increased. The light outcoupling structure 70 having a similar uneven structure to the uneven structure 20 is more effective.

In the organic EL element 1 described above, the amount of light directed to the front can be increased. Therefore, when the direction of traveling light can be controlled to increase the amount of light at an angle at which total reflection does not occur at the surface of the protective layer 10, the light outcoupling structure 70 is dispensable. When the light outcoupling structure 70 is not provided, the production of the organic EL element is simplified. In the embodiment of FIG. 1, a structure having a high light-outcoupling efficiency can be formed without providing the light outcoupling structure 70. On the other hand, the embodiment of FIG. 9 is advantageous when the total reflection at the surface of the protective layer 10 is relatively large.

FIG. 10 is an example of the organic EL element 1. The embodiment of FIG. 10 is a variation of the embodiment of FIG. 1 and may be the same as the embodiment of FIG. 1 except for points described below. The embodiment of FIG. 10 may include one or both of the intermediate refractive index structure 26 described with reference to FIG. 7 and the refractive index adjusting structure 60 described with reference to FIG. 8. The embodiment of FIG. 10 may further include the light outcoupling structure 70 described with reference to FIG. 9. Each member also shown in FIG. 1 is identified by the same reference sign, and the description thereof will be omitted.

The embodiment of FIG. 10 includes a layer, which has a refractive index higher than that of the protective layer 10, disposed between the light emitting layer 41 and the high refractive index layer (first layer) 22. The layer, which has a refractive index higher than that of the protective layer 10, disposed between the light emitting layer 41 and the high refractive index layer 22 is defined as an additional high refractive index layer 80. The additional high refractive index layer 80 adjoins the high refractive index layer (first layer) 22. The additional high refractive index layer 80 functions as a substrate S2. The above-described embodiments represented by FIG. 1 each requires forming the low refractive index layer 21 and the high refractive index layer 22 on the substrate S1 and then forming an organic light emitting body on the high refractive index layer 22. In this case, methods and materials in the stacking process may be limited. On the other hand, in the embodiment of FIG. 10, an organic light emitting body can be formed on one surface of the substrate S2, and the high refractive index layer 22 and the low refractive index layer 21 can be formed on the other surface of the substrate S2. In this case, a preferable stacking process and a preferable material are readily adopted on each of the surfaces. Therefore, the embodiment of FIG. 10 has an advantage that production may be simplified.

In the embodiment of FIG. 10, the additional high refractive index layer 80 serves as the substrate S2 supporting the stack. The protective layer 10 is a layer to protect the low refractive index layer 21 and the high refractive index layer 22 and may, but does not have to, be a substrate. The protective layer 10 may be formed as, for example, a protection film. The protective layer 10 may be formed as a resin layer. The protective layer 10 may formed as an inorganic layer. The protective layer 10 may be made of glass. The presence of the protective layer 10 can reduce exposure of the uneven structure 20 to the outside and can protect the uneven structure 20.

The additional high refractive index layer 80 has a refractive index higher than that of the protective layer 10. A relationship expressed as n₁<n₈ holds true, where n₈ is the refractive index of the additional high refractive index layer 80. The refractive index n₈ of the additional high refractive index layer 80 may be higher than the refractive index n₃ of the high refractive index layer 22. In this case, a relationship expressed as n₃<n₈ holds true. The refractive index n₃ of the additional high refractive index layer 80 may be lower than the refractive index n₃ of the high refractive index layer 22. In this case, a relationship expressed as n₈<n₃ holds true. The refractive index n₈ of the additional high refractive index layer 80 may be higher than the refractive index n₄ of the light emitting layer 41. In this case, a relationship expressed as n₄<n₈ holds true. The refractive index n₈ of the additional high refractive index layer 80 may be lower than the refractive index n₄ of the light emitting layer 41. In this case, a relationship expressed as n₈<n₄ holds true.

The additional high refractive index layer 80 may be made of an appropriate material which expresses a refractive index higher than that of the protective layer 10. Examples of the additional high refractive index layer 80 include high refractive index glass. The high refractive index glass has for example, a refractive index within a range of 1.6 to 2.1. The high refractive index glass may be made of glass doped with metal. Examples of the additional high refractive index layer 80 include sapphire. The sapphire has a refractive index of about 1.77. Moreover, the additional high refractive index layer 80 may be made of a resin film. Examples of the resin film include polyethylene naphthalate (PEN) and polyethylene terephthalate (PET). Polyethylene naphthalate (PEN) may have a refractive index of about 1.77. Polyethylene terephthalate (PET) may have a refractive index of about 1.65.

In FIG. 10, the additional high refractive index layer 80 serves as the substrate S2, but the protective layer 10 may serve as a substrate, and the additional high refractive index layer 80 may be a layer which does not serve as the substrate.

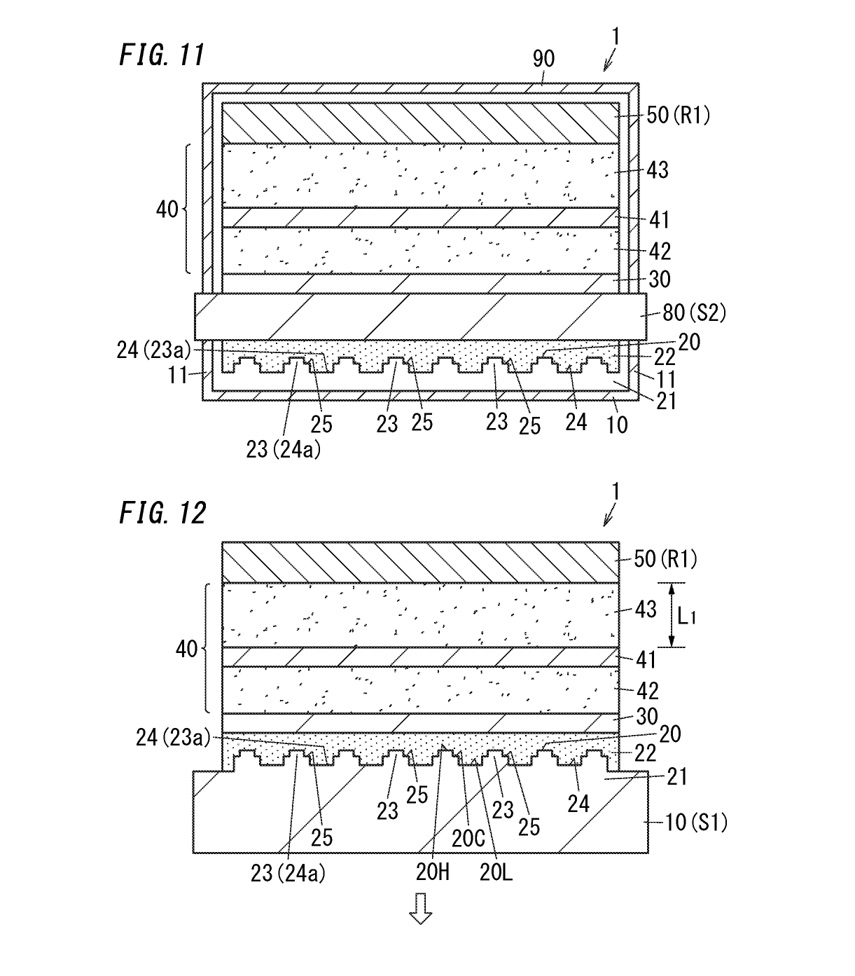

FIG. 11 is an example of the organic EL element 1. The embodiment of the FIG. 11 is a variation of the embodiment of FIG. 10 and may be the same as the embodiment of FIG. 10 except for points described below. Moreover, the embodiment of FIG. 11 may include one or both of the intermediate refractive index structure 26 described with reference to FIG. 7 and the refractive index adjusting structure 60 described with reference to FIG. 8. Moreover, the embodiment of FIG. 11 may further include the light outcoupling structure 70 described with reference to FIG. 9. Each member also shown in FIG. 10 is identified by the same reference sign, and the description thereof will be omitted.

In the embodiment of FIG. 11, the low refractive index layer 21 is a void. The void is an air layer. A space is provided between the protective layer 10 and the high refractive index layer 22. The space serves as the low refractive index layer 21. The protective layer 10 may be made of, for example, glass having a recess. The protective layer 10 includes a spacer 11 on side parts of the protective layer 10 to form the space between the high refractive index layer 22 and the protective layer 10. When the low refractive index layer 21 is the air layer, the refractive index n₂ of the low refractive index layer 21 approximates to the refractive index n₀ of the atmosphere. The refractive index n₂ and the refractive index n₀ may be almost equal to each other. The refractive index n₂ can be equal to the refractive index n₀. Therefore, the refractive index can be easily lowered.

Note that in the organic EL element 1, the organic light emitting body can be generally enclosed and shielded from outside. FIG. 11 shows a structure in which the organic light emitting body is enclosed by an enclosing material 90. It is obvious that also in each of the above-described embodiments represented by FIG. 1, the organic light emitting body may be enclosed by the enclosing material 90. The enclosing material 90 may be made of, for example, glass.

With reference to FIG. 12, an aspect in which the protective layer 10 serves as the second layer, that is, an aspect in which the protective layer 10 is the second layer will be described.

FIG. 12 is a schematic sectional view of an organic EL element 1. The organic EL element 1 includes at least one light emitting layer 41, a first layer, and a second layer. The second layer serves as the protective layer 10. The first layer is defined as the high refractive index layer 22. The high refractive index layer 22 is disposed between the light emitting layer 41 and the light-exiting surface. The second layer (protective layer 10) serves as the low refractive index layer 21. The low refractive index layer 21 is disposed between the high refractive index layer 22 and the light-exiting surface. The low refractive index layer 21 adjoins the high refractive index layer 22. The uneven structure 20 including a plurality of protrusions 23 each having two or more steps is provided at the interface between the high refractive index layer 22 and the low refractive index layer 21. The high refractive index layer 22 means the first layer and may hereinafter be referred to as the first layer 22. Moreover, the low refractive index layer 21 means the second layer and may hereinafter be referred to as the second layer 21.

In the organic EL element 1, relationships expressed as n₀<n₁ and n₂=n₁ are satisfied, where n₀ is the refractive index of the atmosphere, n₁ is the refractive index of the protective layer 10 (second layer), and n₂ is the refractive index of the low refractive index layer (second layer) 21.

The organic EL element 1 includes the protrusions 23 each having two or more steps and has the refractive indices having the relationships described above, and thereby, the direction of light becomes more likely to change. When the direction of light changes, the light-outcoupling efficiency for the wide angle light increases, and the direction of light is more likely to be directed to the front. As a result, the amount of light emitted outside can be increased, which improves the light-outcoupling efficiency. The detailed mechanism of the light-outcoupling efficiency is the same as that described above.

When the second layer is the protective layer 10 as in the embodiment of FIG. 12, these layers are integrated into each other, and therefore, the interface between layers which is formed when the second layer and the protective layer 10 are separate layers can be reduced. Therefore, the light-outcoupling efficiency can further be increased. Moreover, it is possible to reduce light absorption as in a case where the low refractive index layer (second layer) 21 is made of a material other than the protective layer 10. Thus, the light-outcoupling efficiency can be increased. Moreover, the second layer is formed as the protective layer 10 which can be materially firm, the available options for materials for the high refractive index layer (first layer) 22 can be increased, and the available options for processes for fabricating the high refractive index layer (first layer) 22 can also be increased. For example, the high refractive index layer 22 can be formed by a high-temperature process. Thus, a high-quality high refractive index layer 22 can be easily formed.

The protective layer 10 serves as the substrate S1. The protective layer 10, that is, the low refractive index layer (second layer) 21 may be formed as, for example, a low refractive index substrate. The low refractive index substrate is a substrate material having a low refractive index characteristic. Examples of the low refractive index substrate include a low refractive index glass substrate such as quartz glass, bubble containing glass, and a low refractive index resin substrate such as a resin substrate containing fluororesin. The refractive index n₂ of the low refractive index layer 21 (protective layer 10) may be within a similar range to that described above. That is, the refractive index n₂ of the low refractive index layer 21 may be, for example, within a range of 1.0 to 1.5, less than or equal to 1.4, or less than or equal to 1.3.

A preferable one of the above-described aspects in which the second layer is different from the protective layer 10 can be adopted as a preferable aspect in a case where the second layer is the protective layer 10.

That is, in the organic EL element 1, relationships expressed as n₁<n₃ and n₁<n₄ are satisfied, where n₃ is the refractive index of the high refractive index layer (first layer) 22, and n₄ is the refractive index of the light emitting layer 41. This is due to a similar reason to that described above. This aspect provides similar advantages to those described above.

The organic EL element 1 preferably includes a reflective layer R1, which reflects light, disposed on an opposite side of the light emitting layer 41 from the light-exiting surface. In the organic EL element 1, a relationship expressed as L₁≧λ/(3n₅) is preferably satisfied, where n₅ is the refractive index of media between the reflective layer R1 and the light emitting layer 41 closest to the reflective layer R1, λ, is the wavelength of light generated in the light emitting layer 41, and L₁ is the distance between the light emitting layer 41 and the reflective layer R1. This is due to a similar reason to that described above. This aspect provides similar advantages to those described above.

The uneven structure 20 preferably includes a structure (i.e., the intermediate refractive index structure 26) having a refractive index between the refractive index of the first layer (high refractive index layer 22) and the refractive index of the second layer (low refractive index layer 21, that is, the protective layer 10) (see FIG. 7). This is due to a similar reason to that described above. This aspect provides similar advantages to those described above.

In a case where the second layer is the protective layer 10, other preferable aspects, a preferable aspect of the uneven structure 20, description of the uneven structure 20, materials of the members, and the like, are the same as those described above. For example, the light outcoupling structure 70 may be provided between the protective layer 10 (see FIG. 9) and the light-exiting surface. Moreover, the additional high refractive index layer 80 (substrate S2) may be provided between the light emitting layer 41 and the high refractive index layer (first layer) 22 (see FIG. 10).

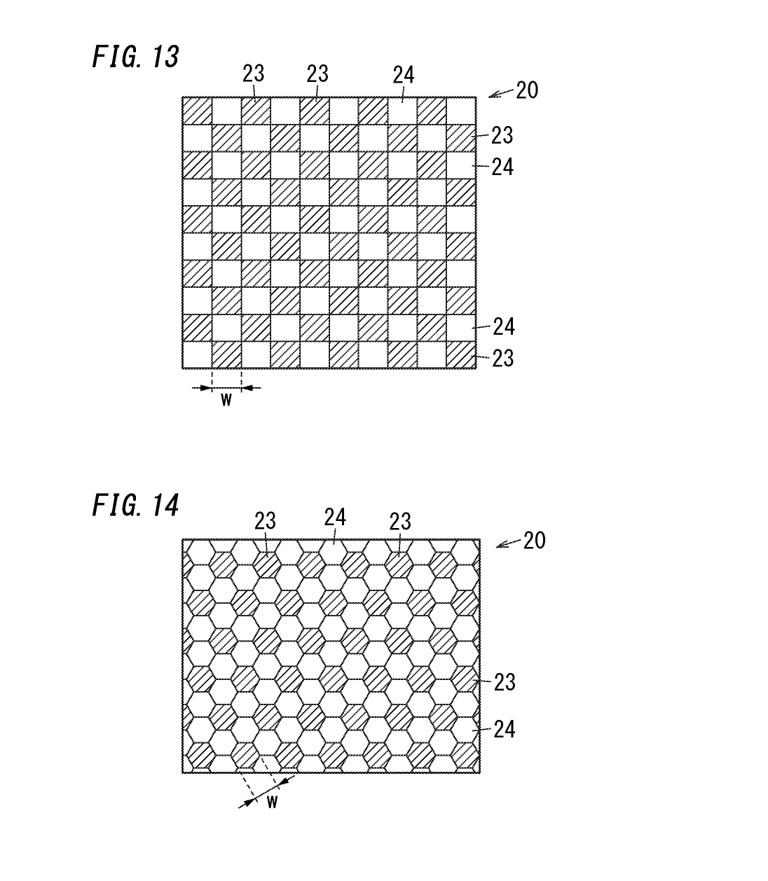

With reference to FIG. 13 and subsequent figures, preferable arrangements of the protrusions 23 and the recesses 24 in the uneven structure 20 will be further described. FIGS. 13 to 16 show the uneven structure 20 viewed in a direction along the normal of the substrate S1. The uneven structure 20 can be said to be in a plan view. The protrusions 23 and the recesses 24 are patterned and schematically illustrated. Portions in which the protrusions 23 are arranged are hatched, and portions in which the recesses 24 are arranged are shown as blanks. As previously described, the protrusions 23 may be changed to the protrusions 23a, and the recesses 24 may be changed to the recesses 24a.

As illustrated in FIGS. 13 to 16, the protrusions 23 and the recesses 24 are preferably arranged by being allocated to uniformly divided sections. In this way, the uneven structure 20 can be formed to have high light-outcoupling efficiency. The protrusions 23 and the recesses 24 are arranged by being allocated to sections each having a width w. The width w is also referred to a border width.

FIGS. 13 and 14 show preferable examples of the arrangement of protrusions and recesses, and in these examples, a plurality of protrusions 23 is regularly arranged. Such a regular arrangement of the protrusions 23 can increase the light-outcoupling efficiency according to a predetermined wavelength and/or a predetermined direction of light, and therefore, the entire light-outcoupling efficiency can be increased. The protrusions 23 are preferably arranged to have periodicity. The protrusions 23 may be arranged at regular intervals.

The example of FIG. 13 shows that the protrusions 23 are arranged in a quadrangular lattice. The quadrangular lattice may have a checkboard pattern. The protrusions 23 and the recesses 24 are alternately allocated and arranged. The protrusions 23 are arranged in a check pattern. In the entire surface, the percentage of the protrusions 23 is 50%. The protrusions 23 may be arranged at equal distance in rows and columns.

An example illustrated in FIG. 14 shows that the protrusions 23 are arranged in a hexagonal lattice. The hexagonal lattice may have a honeycomb structure. Around each protrusion 23, recesses 24 are arranged. The protrusions 23 may be arranged at an equal distance in three directions. In the entire surface, the proportion of the protrusions 23 may be ⅓. Here, the protrusions 23 and the recesses 24 may be exchanged. When the protrusions 23 are joined to each other to form one protrusion, the recesses 24 may be considered to be protrusions 23a forming the uneven structure 20 as previously described. Alternatively, the arrangement of the hexagonal lattice may be used, and the size of the hexagon of each protrusion 23 may be increased to increase the percentage of the protrusions 23 in the entire surface to about 50%. The arrangement of the hexagonal lattice may be a finely filled arrangement.

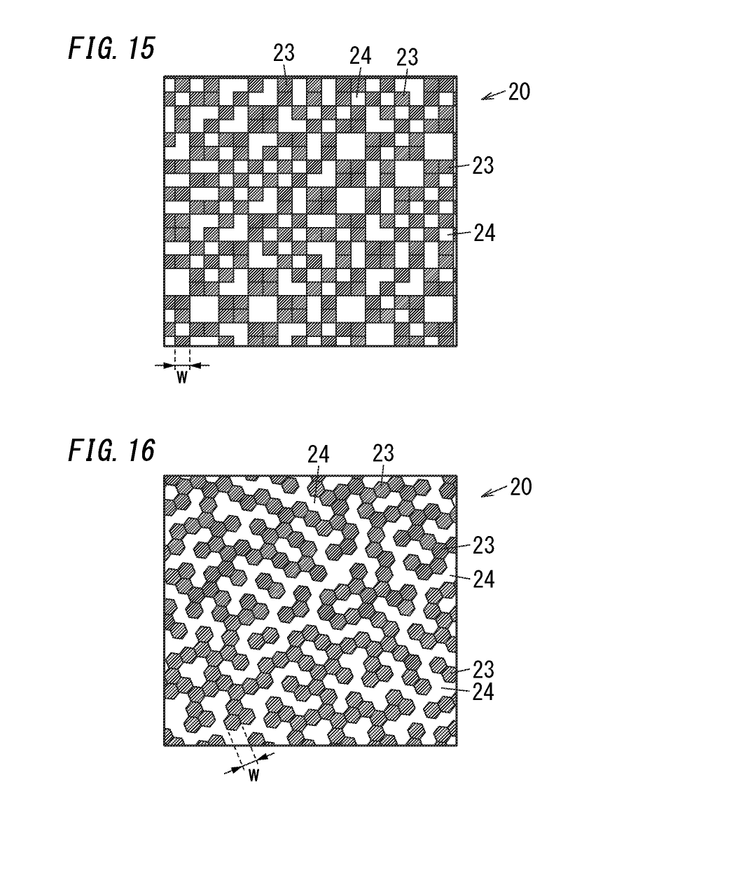

FIGS. 15 and 16 show preferable examples of the arrangement of protrusions and recesses, and in these examples, the protrusions are randomly arranged. Such a random arrangement of the protrusions 23 can increase the light-outcoupling efficiency independently of the wavelength and the direction of light, and therefore, the entire light-outcoupling efficiency can be increased. Moreover, viewing angle dependency can be reduced.

FIG. 15 shows the protrusions 23 randomly arranged in a quadrangular lattice. FIG. 16 shows the protrusions 23 randomly arranged in a hexagonal lattice. Note that randomness is controlled in FIG. 15 and FIG. 16. Specifically, control is performed such that a predetermined number or more of the protrusions 23 are not aligned in the same direction. Moreover, control is performed such that a predetermined number or more of the recesses 24 are not aligned in the same direction. In FIG. 15, more than two protrusions 23 are not arranged continuously, and more than two recesses 24 are not arranged continuously. The number of continuously arranged protrusions 23 and the number of continuously arranged recesses 24 are each less than or equal to two. In FIG. 16, more than three protrusions 23 are not arranged continuously, and more than three recesses 24 are not arranged continuously. The number of continuously arranged protrusions 23 and the number of continuously arranged recesses 24 are each less than or equal to three. Therefore, the arrangement is not completely random, but the randomness is controlled, thereby further increasing the light-outcoupling efficiency. When the randomness is controlled, the boundaries between the protrusions 23 and the recesses 24 may increase.

When a protrusion 23 and a protrusion 23 are joined to each other, a tip of the protrusion 23 and a tip of the protrusion 23 may, but does not have to, be connected to each other. Preferably, portions in which the tips of the protrusions 23 are connected to each other and portions in which the tips of the protrusions 23 are not connected to each other are randomly arranged. In this way, the randomness increases, thereby increasing the light-outcoupling efficiency. The tip of the protrusion 23 means the uppermost step of the protrusion 23. Moreover, when the protrusion 23 and the protrusion 23 are connected to each other, two or more step portions 25 may, but do not have to, be connected to each other. Preferably, portions in which two or more step portions 25 are connected to each other and portions in which two or more step portions 25 are not connected to each other are randomly arranged. In this way, the randomness increases, thereby increasing the light-outcoupling efficiency. The randomness of the recesses 24 may also be controlled in a similar manner.

FIGS. 13 to 16 show the allocation of the protrusions 23 to the lattice. As previously described, the protrusions 23 each have two or more steps and include one or more step portions 25. As long as each protrusion 23 has the step portion 25, the protrusion 23 may have any shape in a plan view. Examples of the shape of the protrusion 23 in a plan view include a quadrangular shape, a hexagonal shape, a polygonal shape, and a circular shape. Examples of the shape of each recess 24 in a plan view include a quadrangular shape, a polygonal shape, and a circular shape. The uppermost step of the protrusion 23 and the step portion 25 may have a similar shape in a plan view.

The width of the protrusion 23 may randomly change. The width of the recess 24 may randomly change. In the uneven structure, the percentage of the protrusions 23 and the percentage of the recesses 24 may be accordingly changed. The percentage of the protrusions 23 may be within the range of 30% to 70%. The percentage of the recesses 24 may be within the range of 30% to 70%.

The base material S10 is incorporated into the organic EL element 1. The base material S10 includes a first layer and a second layer adjoining the first layer. The uneven structure 20 including a plurality of protrusions 23 each having two or more steps is provided at the interface between the first layer and the second layer. The base material S10 includes the protective layer 10. The protective layer 10 is a layer adjoining the second layer or is the second layer. The relationships expressed as n₀<n₁ and n₂≦n₁ are satisfied, where n₀ is the refractive index of the atmosphere, n₁ is the refractive index of the protective layer 10, and n₂ is the refractive index of the second layer.

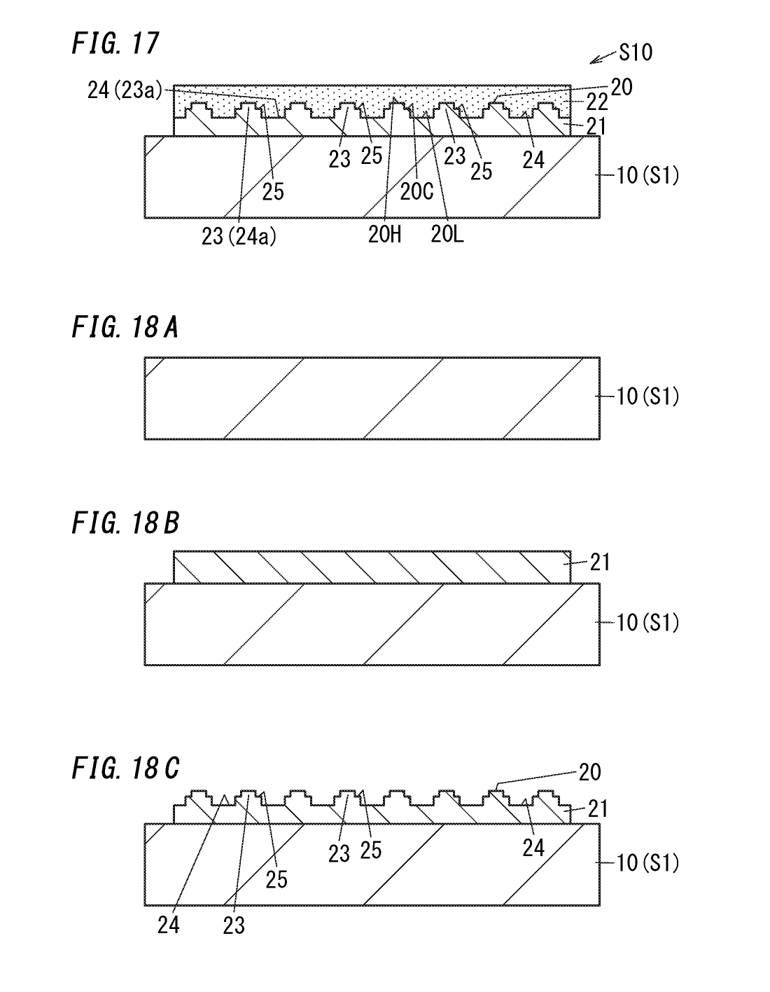

FIG. 17 is a sectional view illustrating an example of the base material S10. This aspect represents the base material S10 in a case where the protective layer 10 is a layer adjoining the second layer, that is, in a case where the protective layer 10 is a layer different from the second layer. The base material S10 includes the high refractive index layer (first layer) 22, the low refractive index layer (second layer) 21 adjoining the high refractive index layer 22, and the protective layer 10 adjoining the low refractive index layer 21. The uneven structure 20 including the plurality of protrusions 23 each having two or more steps is provided at the interface between the high refractive index layer 22 and the low refractive index layer 21. The relationships expressed as n₀<n₁ and n₂<n₁ hold true, where n₂ is the refractive index of the atmosphere, n₁ is the refractive index of the protective layer 10, and m is the refractive index of the low refractive index layer 21. The base material S10 can provide the organic EL element 1 excellent in light-outcoupling efficiency.

The base material S10 may be used for the organic EL element 1. FIG. 17 shows the base material S10 applied to the organic EL element 1 of FIG. 1, but the base material S10 may be applied to the organic EL element 1 described with reference to the other figures (where the protective layer 10 and the second layer are different from each other). The base material S10 may be used for elements other than the organic EL element 1. The base material S10 may be used for optical devices. A preferable structure of the base material S10 may be the structure described in relation to the organic EL element 1. Each member also shown in the above structure is identified by the same reference sign, and the description thereof will be omitted. The detailed structure of the base material S10 will be understood from the description above. A plurality of layers is stacked on the base material S10, thereby fabricating the organic EL element 1.

FIGS. 18A to 18C show an example of a method for fabricating the base material S10. The base material S10 shown in FIG. 17 is fabricated through processes of FIGS. 18A to 18C. As illustrated in FIG. 18A, a protective layer 10 is first prepared to fabricate the base material S10. The protective layer 10 is, for example, a glass substrate. The glass substrate may be cleaned. Next, as illustrated in FIG. 18B, a low refractive index layer (second layer) 21 is formed on the protective layer 10. Note that, in this step, the low refractive index layer 21 does not have to be provided with protrusions and recesses. Then, as illustrated in FIG. 18C, the protrusions and the recesses are formed on a surface of the low refractive index layer 21 by an imprinting method. In this way, the low refractive index layer 21 is provided with an uneven structure 20. Finally, a high refractive index layer (first layer) 22 is formed on the low refractive index layer 21 (see FIG. 17). The base material S10 is thus fabricated.

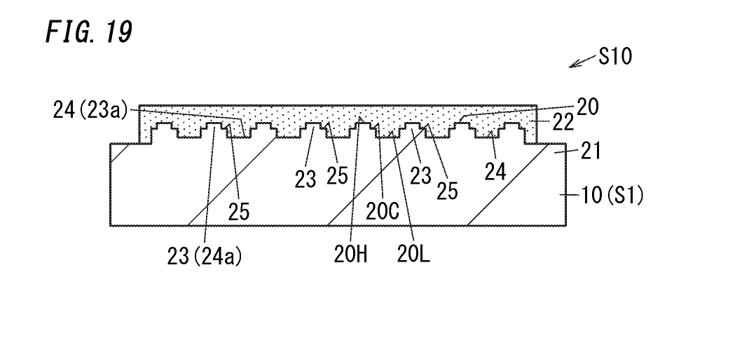

FIG. 19 is a sectional view illustrating another example of the base material S10. This aspect shows the base material S10 in a case where the protective layer 10 serves as the second layer, that is, in a case where the protective layer 10 is the second layer. The base material S10 includes a high refractive index layer (first layer) 22 and a low refractive index layer (second layer) 21 adjoining the high refractive index layer 22. The low refractive index layer 21 serves as the protective layer 10. An uneven structure 20 including a plurality of protrusions 23 each having a two or more-stepped protrusion is provided at an interface between the high refractive index layer 22 and the low refractive index layer 21. The relationships expressed as n₀<n₁ and n₂=n₁ are satisfied, where n₀ is the refractive index of the atmosphere, n₁ is the refractive index of the protective layer 10, and n₂ is the refractive index of the low refractive index layer 21. The base material S10 can provide an organic EL element 1 excellent in light-outcoupling efficiency.

The base material S10 may be used for the organic EL element 1. FIG. 19 shows the base material S10 applied to the organic EL element 1 of FIG. 12, but the base material S10 may be applied to an organic EL element 1 modified from that of FIG. 12. The base material S10 may be used for a device other than the organic EL element 1. The base material S10 can be used for optical devices. A preferable structure of the base material S10 may be the structure described in relation to the organic EL element 1. Each member also shown in the above structure is identified by the same reference sign, and the description thereof will be omitted. The detailed structure of the base material S10 will be understood from the description above. A plurality of layers is stacked on the base material S10, thereby fabricating the organic EL element 1.

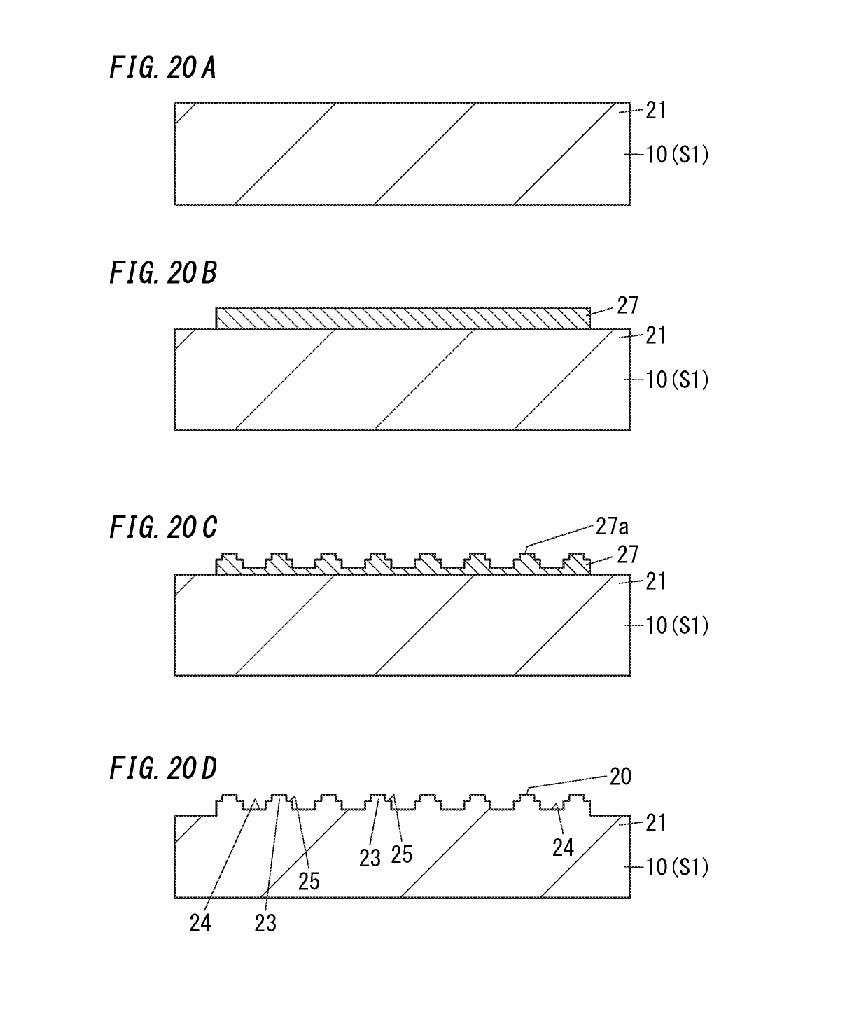

FIGS. 20A to 20D show an example of a method for fabricating the base material S10. The base material S10 of FIG. 19 is fabricated through processes of FIGS. 20A to 20D. As illustrated in FIG. 20A, a protective layer 10 (a low refractive index layer 21, that is, a second layer) is first prepared to fabricate the base material S10. The protective layer 10 is, for example, a glass substrate. Specifically, a low refractive index glass substrate is shown as an example. The glass substrate may be cleaned. Next, as illustrated in FIG. 20B, a resist layer 27 is formed on the protective layer 10. At this step, the resist layer 27 does not have to be provided with protrusions and recesses. The resist layer 27 is made of, for example, resin. Then, as illustrated in FIG. 20C, the protrusions and the recesses are formed on a surface of the resist layer 27 by an imprinting method. At this time, the protrusions and the recesses are formed based on a previously considered selected ratio of the etching property of the resist layer 27 and the etching property of the protective layer 10. For example, when the selected ratio of the both etching properties is 1:1, targeted protrusions and recesses are formed on the resist layer 27. In this way, the resist layer 27 is provided with an uneven structure 27a. Then, a surface of the resist layer 27 undergoes etching. The etching may be performed by gradually grinding layers from the surface along the protrusions and recesses on the surface. Either one of wet etching or dry etching may be employed. The protective layer 10 undergoes etching in a region where the resist layer 27 is removed by etching. In this way, etching of the resist layer 27 and the protective layer 10 are carried out. At this time, the protrusions and the recesses of the resist layer 27 vary the etching amount of the protective layer 10. Thus, as illustrated in FIG. 20D, the protrusions and recesses are provided to the protective layer 10. In this way, the protrusions and recesses of the resist layer 27 are transferred to the protective layer 10. The remaining resist layer 27 may be removed by cleaning. Finally, a high refractive index layer (first layer) 22 is formed on the protective layer 10 (low refractive index layer 21) (see FIG. 19). The high refractive index layer 22 may be formed by applying a material of the high refractive index layer 22 on the protective layer 10. The base material S10 is thus fabricated. As described above, the high refractive index layer 22 is formed on the protective layer 10, which increases the available options for materials and processes, thereby facilitating its formation.

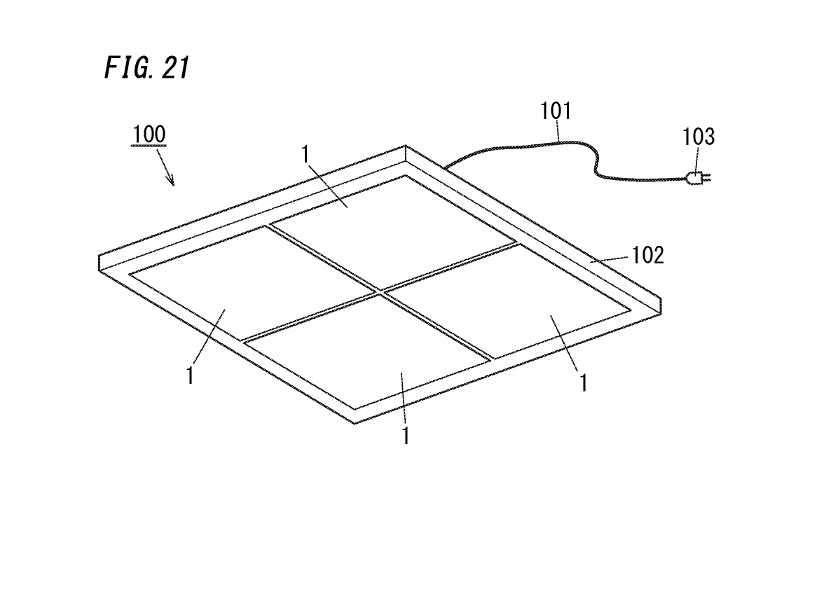

FIG. 21 is a perspective view illustrating an example of a light emitting device. A light emitting device 100 is disclosed. The light emitting device 100 includes the organic EL element 1 and a cable 101. The light emitting device 100 includes a body 102 and a plug 103. Examples of the light emitting device 100 includes panels, lighting devices, on-board lighting devices, displays, signage, and lighting devices installed in building materials. The example of FIG. 21 is a lighting device. The organic EL element 1 is applicable to the lighting device. In the figure, a plurality of (four) organic EL elements 1 is in a planar arrangement. The light emitting device 100 may include one organic EL element 1. The organic EL element 1 is accommodated in the body 102. Electric power is supplied via the plug 103 and the cable 101 to enable the organic EL element 1 to emit light, and the light is emitted from the light emitting device 100. The color of the light of the organic EL element 1 may be white. In this case, a light emitting device 100 which emits white light is obtained.

1. An organic electroluminescent element, comprising:
at least one light emitting layer;
a first layer disposed between the at least one light emitting layer and a light-exiting surface of the organic electroluminescent; and
a second layer disposed between the first layer and the light-exiting surface and adjoining the first layer,
an uneven structure including a plurality of protrusions each having two or more steps being provided at an interface between the first layer and the second layer,
the organic electroluminescent element comprising a protective layer which is a layer disposed between the second layer and the light-exiting surface,
relationships expressed as n₀<n₁ and n₂≦n₁ being satisfied, where n₀ is a refractive index of an atmosphere, n₁ is a refractive index of the protective layer, and n₂ is a refractive index of the second layer.

2. The organic electroluminescent element according to claim 1, wherein
relationships expressed as n₁<n₃ and n₁<n₄ are satisfied, where n₃ is a refractive index of the first layer, and n₄ is a refractive index of the at least one light emitting layer.

3. The organic electroluminescent element according to claim 1, further comprising
a reflective layer, which reflects light, disposed on an opposite side of the at least one light emitting layer from the light-exiting surface, wherein
a relationship expressed as L₁≧λ(3n₅) is satisfied, wherein n₅ is a refractive index of a medium between the reflective layer and a light emitting layer which is one of the at least one light emitting layer and is located closest to the reflective layer, λ is a wavelength of light generated in the light emitting layer, and L₁ is a distance between the reflective layer and the light emitting layer.

4. The organic electroluminescent element according to claim 1, wherein
the uneven structure includes a structure having a refractive index between the refractive index of the first layer and the refractive index of the second layer.

5. The organic electroluminescent element according to claim 1, wherein
the refractive index n₁ and the refractive index n₂ satisfy a relationship expressed as n₂<n₁.

6. The organic electroluminescent element according to claim 5, further comprising
a structure, which has a refractive index lower than the refractive index of the protective layer, disposed between the protective layer and the second layer.

7. (canceled)

8. The organic electroluminescent element according to claim 1, wherein
the protrusions are regularly arranged.

9. The organic electroluminescent element according to claim 1, wherein
the protrusions are randomly arranged.

10. The organic electroluminescent element according to claim 1, further comprising
a layer, which serves as a substrate and has a refractive index higher than the refractive index of the protective layer, disposed between the light emitting layer and the first layer and adjoining the first layer.

11. The organic electroluminescent element according to claim 1, further comprising
a light outcoupling structure disposed between the protective layer and the light-exiting surface.

12. A base material, comprising:
a first layer; and
a second layer adjoining the first layer,
an uneven structure including a plurality of protrusions each having two or more steps being provided at an interface between the first layer and the second layer,
the base material comprising a protective layer which is a layer adjoining the second layer,
relationships expressed as n₀<n₁ and n₂≦n₁ being satisfied, where n₀ is a refractive index of an atmosphere, n₁ is a refractive index of the protective layer, and n₂ is a refractive index of the second layer.

13. The base material according to claim 12, wherein
the refractive index n₁ and the refractive index n₂ satisfy a relationship expressed as n₂<n₁.

14. (canceled)

15. A light emitting device, comprising:
the organic electroluminescent element according to claim 1; and
a cable.
